(19) United States
(12) Patent Application Publication
(10) Pub. No.: US 2022/0238540 A1
(43) Pub. Date: Jul. 28, 2022

(54) MEMORY DEVICES AND METHODS OF MANUFACTURING THEREOF

(71) Applicant: Taiwan Semiconductor Manufacturing Company, Ltd., Hsinchu (TW)

(72) Inventors: Chien-Ying Chen, Chiayi City (TW); Yao-Jen Yang, Hsinchu City (TW); Chia-En Huang, Xinfeng Township (TW)

(73) Assignee: Taiwan Semiconductor Manufacturing Company, Ltd., Hsinchu (TW)

(21) Appl. No.: 17/482,094

(22) Filed: Sep. 22, 2021

Related U.S. Application Data
(60) Provisional application No. 63/140,323, filed on Jan. 22, 2021.

(51) Int. Cl. H01L 27/112

(52) U.S. Cl. CPC H01L 27/11206

(57) ABSTRACT

A memory device is disclosed. The memory device includes a first transistor and a first capacitor electrically coupled to the first transistor, the first transistor and the first capacitor forming a first one-time-programmable (OTP) memory cell. The first capacitor has a first bottom metal terminal, a first top metal terminal, and a first insulation layer interposed between the first bottom and first top metal terminals. The first insulation layer comprises a first portion, a second portion separated from the first portion, and a third portion vertically extending between the first portion and the second portion. The first bottom metal terminal is directly below and in contact with the first portion of the first insulation layer.

### CROSS-REFERENCE TO RELATED APPLICATION

This application claims priority to and the benefit of U.S. Provisional Application No. 63/140,323, filed Jan. 22, 2021, entitled “A MIM TYPE ONE-TIME-PROGRAMMABLE (OTP) DEVICE,” which is incorporated herein by reference in its entirety for all purposes.

### BACKGROUND

A one-time programmable (OTP) device is a type of non-volatile memory (NVM) often used for read-only memory (ROM). When the OTP device is programmed, the device cannot be reprogrammed. Common types include electrical fuses which use metal fuses (e.g., eFuse) and anti-fuse which uses gate dielectrics. One problem with typical OTP devices is high voltage endurance which causes degradation in the OTP device over time. As technology continues to advance and follow Moore's law, it is desirable to have devices that require low voltages and small cell areas.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic block diagram of a memory device, in accordance with some embodiments.

FIGS. 2A, 2B, and 2C are schematic circuit diagrams of a memory cell in various operations, in accordance with some embodiments.

FIGS. 3A and 3B illustrate cross-sectional views of a transistor and a capacitor, in accordance with some embodiments.

FIG. 4A illustrates a circuit schematic of a memory device, in accordance with some embodiments.

FIG. 4B illustrates a layout of a capacitor for the memory device illustrated in FIG. 4A, in accordance with some embodiments.

FIGS. 4C, 4D, 4E, and 4F illustrate top-down views of various layers of the memory device of FIG. 4A, in accordance with some embodiments.

FIGS. 4G, 4H, 4I, 4J, 4K, 4L, and 4M illustrate various layers of a memory cell of the memory device of FIG. 4A, in accordance with some embodiments.

FIG. 5A illustrates a circuit schematic of a memory device, in accordance with some embodiments.

FIG. 5B illustrates a layout of a capacitor for the memory device illustrated in FIG. 5A, in accordance with some embodiments.

FIGS. 5C, 5D, 5E, and 5F illustrate top-down views of various layers of the memory device of FIG. 5A, in accordance with some embodiments.

FIGS. 5G, 5H, 5I, 5J, 5K, 5L, and 5M illustrate various layers of a memory cell of the memory device of FIG. 5A, in accordance with some embodiments.

FIG. 6A illustrates a circuit schematic of a memory device, in accordance with some embodiments.

FIG. 6B illustrates a layout of a capacitor for the memory device illustrated in FIG. 6A, in accordance with some embodiments.

FIGS. 6C, 6D, 6E, and 6F illustrate top-down views of various layers of the memory device of FIG. 6A, in accordance with some embodiments.

FIGS. 6G, 6H, 6I, 6J, 6K, 6L, and 6M illustrate various layers of a memory cell of the memory device of FIG. 6A, in accordance with some embodiments.

FIG. 7A illustrates a circuit schematic of a memory device, in accordance with some embodiments.

FIG. 7B illustrates a layout of a capacitor for the memory device illustrated in FIG. 7A, in accordance with some embodiments.

FIGS. 7C, 7D, 7E, and 7F illustrate top-down views of various layers of the memory device of FIG. 7A, in accordance with some embodiments.

FIGS. 7G, 7H, 7I, 7J, 7K, 7L, and 7M illustrate various layers of a memory cell of the memory device of FIG. 7A, in accordance with some embodiments.

FIG. 8 illustrates a flow chart of an example method for making a MIM capacitor, in accordance with some embodiments.

FIGS. 9A, 9B, 9C, 9D, 9E, 9F, 9G, 9H, 9I, and 9J illustrate cross-sectional views of an example MIM capacitor during various fabrication stages, made by the method of FIG. 8, in accordance with some embodiments.

FIG. 10 illustrates a cross-section of the memory device illustrated in FIG. 3B, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuits (ICs) sometimes include one-time-programmable (OTP) memories to provide non-volatile memory (NVM) in which data are not lost when the IC is powered off. One type of the OTP devices includes anti-fuse memories. An anti-fuse memory cell typically includes a programming MOS transistor (or MOS capacitor) and at least one reading MOS transistor. A gate dielectric of the programming MOS transistor is broken down to cause the gate and the source or drain region of the programming MOS transistor to be interconnected. One disadvantage of anti-fuse is the high voltage required to program the device (typically about 5V). Another type of OTP device includes the electrical fuse (eFuse) which uses metal fuses. An eFuse is programmed by electrically blowing a strip of metal or poly with a flow of high-density current using I/O voltage. eFuses are programmed with a program voltage of about 1.8V which is advantageous over antifuse. However, eFuses require substantially more area for one memory cell. For example, a typical eFuse cell area is about 1.769 μm², whereas a typical antifuse memory cell area is about 0.0674 μm². Therefore, eFuses are not desirable for applications that require dense memories, but as discussed above, antifuse requires high voltages which is undesirable for low power applications.

In some embodiments, a memory cell has a one-transistor-one-capacitor (1T1C) configuration having a capacitor and a transistor coupled in series between a bit line and ground. A gate terminal of the transistor is coupled to a word line. The capacitor is a metal-inter (or insulator)-metal (MIM) capacitor over the transistor. An insulating material of the capacitor is configured to break down under a predetermined break-down voltage or higher applied across the insulating material. When the insulating material is not yet broken down, the memory cell stores a first datum, e.g., logic “1.” When the insulating material is broken down, the memory cell stores a second datum, e.g., logic “0.” Compared to other approaches such as gate oxide anti-fuses and metal fuses, the memory cell in at least one embodiment provides one or more improvements including, but not limited to, smaller chip area, lower program voltage, lower disturb voltage or the like. An OTP device including the MIM capacitor of the disclosed technology can be advantageous over the antifuse device and eFuse device because an OTP memory cell including the MIM capacitor can have a lower cell area (about 0.0378 μm² to about 0.0674 μm²) and a low program voltage (less than about 1.8V) which is an advantageous combination over the eFuse and antifuse technologies.

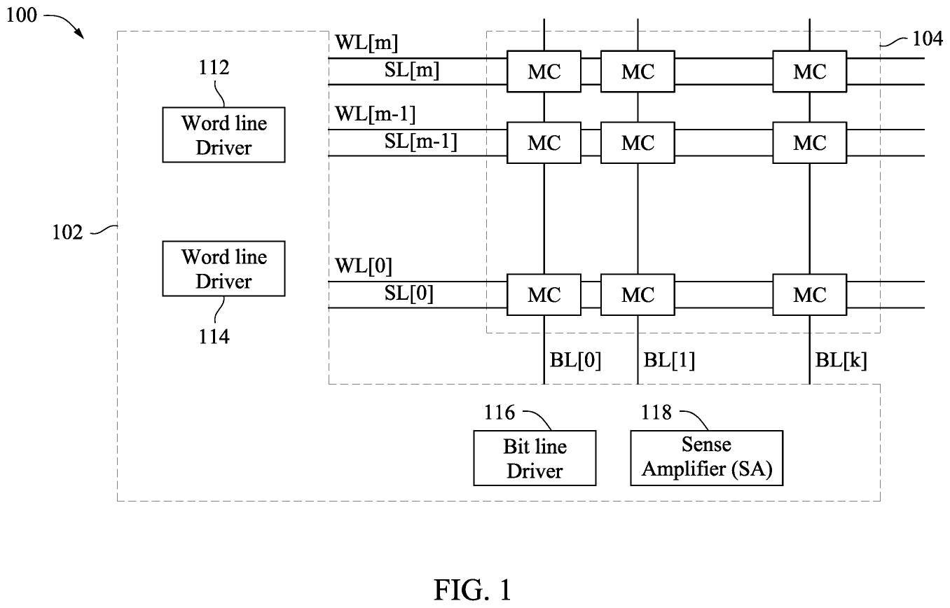

FIG. 1 illustrates a schematic block diagram of a memory device 100, in accordance with some embodiments. A memory device is a type of an IC device. In at least one embodiment, a memory device is an individual IC device. In some embodiments, a memory device is included as a part of a larger IC device which comprises circuitry other than the memory device for other functionalities.

The memory device 100 comprises at least one memory cell MC and a controller (also referred to as “control circuit”) 102 coupled to control an operation of the memory cell MC. In the example configuration in FIG. 1, the memory device 100 comprises a plurality of memory cells MC arranged in a plurality of columns and rows in a memory array 104. The memory device 100 further comprises a plurality of word lines WL[0] to WL[m] extending along the rows, a plurality of source lines SL[0] to SL[m] extending along the rows, and a plurality of bit lines (also referred to as “data lines”) BL[0] to BL[k] extending along the columns of the memory cells MC. Each of the memory cells MC is coupled to the controller 102 by at least one of the word lines, at least one of the source lines, and at least one of the bit lines. Examples of word lines include, but are not limited to, read word lines for transmitting addresses of the memory cells MC to be read from, write word lines for transmitting addresses of the memory cells MC to be written to, or the like. In at least one embodiment, a set of word lines is configured to perform as both read word lines and write word lines. Examples of bit lines include read bit lines for transmitting data read from the memory cells MC indicated by corresponding word lines, write bit lines for transmitting data to be written to the memory cells MC indicated by corresponding word lines, or the like. In at least one embodiment, a set of bit lines is configured to perform as both read bit lines and write bit lines. In one or more embodiments, each memory cell MC is coupled to a pair of bit lines referred to as a bit line and a bit line bar. The word lines are commonly referred to herein as WL, the source lines are commonly referred to herein as SL, and the bit lines are commonly referred to herein as BL. Various numbers of word lines and/or bit lines and/or source lines in the memory device 100 are within the scope of various embodiments. In at least one embodiment, the source lines SL are arranged in the columns, rather than in the rows as shown in FIG. 1. In at least one embodiment, the source lines SL are omitted.

In the example configuration in FIG. 1, the controller 102 comprises a word line driver 112, a source line driver 114, a bit line driver 116, and a sense amplifier (SA) 118 which are configured to perform at least one of a read operation or a write operation. In at least one embodiment, the controller 102 further includes one or more clock generators for providing clock signals for various components of the memory device 100, one or more input/output (1/O) circuits for data exchange with external devices, and/or one or more controllers for controlling various operations in the memory device 100. In at least one embodiment, the source line driver 114 is omitted.

The word line driver 112 is coupled to the memory array 104 via the word lines WL. The word line driver 112 is configured to decode a row address of the memory cell MC selected to be accessed in a read operation or a write operation. The word line driver 112 is configured to supply a voltage to the selected word line WL corresponding to the decoded row address, and a different voltage to the other, unselected word lines WL. The source line driver 114 is coupled to the memory array 104 via the source lines SL. The source line driver 114 is configured to supply a voltage to the selected source line SL corresponding to the selected memory cell MC, and a different voltage to the other, unselected source lines SL. The bit line driver 116 (also referred as “write driver”) is coupled to the memory array 104 via the bit lines BL. The bit line driver 116 is configured to decode a column address of the memory cell MC selected to be accessed in a read operation or a write operation. The bit line driver 116 is configured to supply a voltage to the selected bit line BL corresponding to the decoded column address, and a different voltage to the other, unselected bit lines BL. In a write operation, the bit line driver 116 is configured to supply a write voltage (also referred to as “program voltage”) to the selected bit line BL. In a read operation, the bit line driver 116 is configured to supply a read voltage to the selected bit line BL. The SA 118 is coupled to the memory array 104 via the bit lines BL. In a read operation, the SA 118 is configured to sense data read from the accessed memory cell MC and retrieved through the corresponding bit lines BL. The described memory device configuration is an example, and other memory device configurations are within the scopes of various embodiments. In at least one embodiment, the memory device 100 is a one-time programmable (OTP) non-volatile memory, and the memory cells MC are OTP memory cells. Other types of memory are within the scopes of various embodiments. Example memory types of the memory device 100 include, but are not limited to, electrical fuse (eFuse), anti-fuse, magnetoresistive random-access memory (MRAM), or the like.

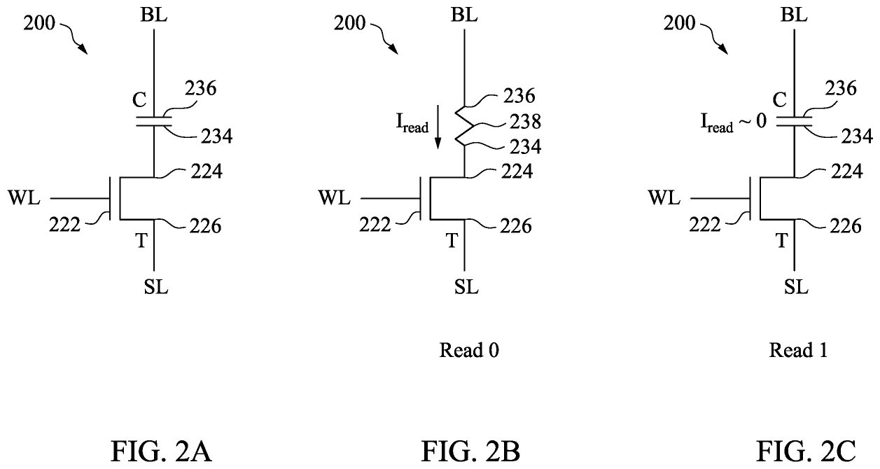

FIGS. 2A-2C are schematic circuit diagrams of a memory cell 200 in various operations, in accordance with some embodiments. In at least one embodiment, the memory cell 200 corresponds to at least one of the memory cells MC in the memory device 100.

In FIG. 2A, the memory cell 200 comprises a capacitor C and a transistor T. The transistor T has a gate terminal 222 coupled to a word line WL, a first terminal 224, and a second terminal 226. The capacitor C has a first end 234 coupled to the first terminal 224 of the transistor T, a second end 236 coupled to a bit line BL, and an insulating material (not shown in FIG. 2A) between the first end 234 and the second end 236. The insulating material is configured to break down under a predetermined break-down voltage or higher applied between the first end 234 and the second end 236.

In the example configuration in FIG. 2A, the second terminal 226 is coupled to a source line SL. In other words, the capacitor C and the transistor T are coupled in series between the bit line BL and the source line SL. In at least one embodiment, the word line WL corresponds to at least one of the word lines WL in the memory device 100, the source line SL corresponds to at least one of the source lines SL in the memory device 100, and the bit line BL corresponds to at least one of the bit lines BL in the memory device 100. In at least one embodiment, the source line SL is omitted, and the second terminal 226 is coupled to a node of a predetermined voltage. Examples of a predetermined voltage include, but are not limited to, a ground voltage VSS, a positive power supply voltage VDD, or the like.

Examples of the transistor T include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like. The first terminal 224 is a source/drain of the transistor T, and the second terminal 226 is another source/drain of the transistor T. In the example configuration described with respect to FIG. 2A, the transistor T is an NMOS transistor, the first terminal 224 is a drain and the second terminal 226 is a source of the transistor T. Other configurations including PMOS transistors instead of NMOS transistors are within the scopes of various embodiments.

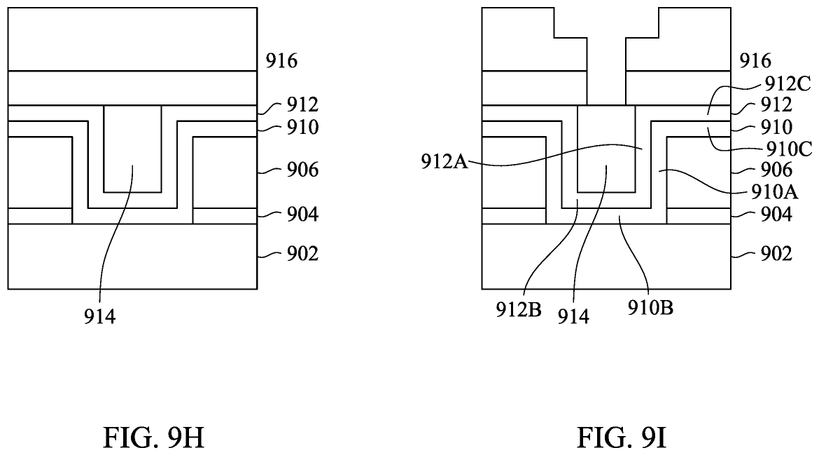

An example of the capacitor C includes, but is not limited to, an MIM capacitor. Other capacitor configurations, e.g., MOS capacitor, are within the scopes of various embodiments. An MIM capacitor comprises a lower electrode (i.e., lower terminal) corresponding to one of the first end 234 or the second end 236, an upper electrode (i.e., upper terminal) corresponding to the other of the first end 234 or the second end 236, and the insulating material interposed between the lower electrode and the upper electrode. Example materials of the insulating material include, but are not limited to, silicon oxide, silicon dioxide, aluminum oxide, hafnium oxide, tantalum oxide, ZrO, TiO2, HfOx, a high-k dielectric, or the like. Examples of high-k dielectrics include, but are not limited to, zirconium dioxide, hafnium dioxide, zirconium silicate, hafnium silicate, or the like. In at least one embodiment, the insulating material of the capacitor C is the same as or similar to a gate dielectric included in a transistor, such as the transistor T. In at least one embodiment, the transistor T is formed over a semiconductor substrate in a front-end-of-line (FEOL) processing, and then the capacitor C is formed as an MIM capacitor in a back-end-of-line (BEOL) processing over the transistor T. Further example structures and example manufacturing processes of a memory cell in accordance with some embodiments are described with respect to FIGS. 8, 9A-9J and 10.

In some embodiments, operations of the memory cell 200 are controlled by a controller, such as the controller 102 of the memory device 100. For example, when the memory cell 200 is selected in a programming operation (also referred to as “write operation”), the controller 102 is configured to apply a turn-ON voltage via the word line WL to the gate terminal 222 of the transistor T to turn ON the transistor T. The controller 102 is further configured to apply a program voltage via the bit line BL to the second end 236 of the capacitor C, and apply a ground voltage VSS to the source line SL. In at least one embodiment, the source line SL is grounded at all times. While the transistor T is turned ON by the turn-ON voltage and electrically couples the first end 234 of the capacitor C to the ground voltage VSS on the source line SL, the program voltage applied to the second end 236 from the bit line BL causes a predetermined break-down voltage or higher to be applied between the first end 234 and the second end 236 of the capacitor C. As a result, a short circuit occurs in the insulating material of the capacitor C under the applied break-down voltage or higher. In other words, the insulating material is broken down and becomes a resistive structure, for example, as described with respect to FIG. 2B. The broken down insulating material corresponds to a first datum, or a first logic value, stored in the memory cell 200. In at least one embodiment, the first datum corresponding to the broken-down insulating material is logic “0.”

When the memory cell 200 is not selected in a programming operation, the controller 102 is configured to not apply at least one of the turn-ON voltages, the program voltage or the ground voltage VSS to the corresponding gate terminal 222, bit line BL or source line SL. As result, the insulating material of the capacitor C is not broken down, and the capacitor C remains a capacitive structure, for example, as described with respect to FIG. 2C. The insulating material not yet broken down corresponds to a second datum, or a second logic value, stored in the memory cell 200. In at least one embodiment, the second datum corresponding to the insulating material not yet broken down is logic “1.”

When the memory cell 200 is selected in a read operation, the controller 102 is configured to apply a turn-ON voltage via the word line WL to the gate terminal 222 of the transistor T to turn ON the transistor T. The controller 102 is further configured to apply a read voltage via the bit line BL to the second end 236 of the capacitor C, and apply a ground voltage VSS to the source line SL. In at least one embodiment, the source line SL is grounded at all times. While the transistor T is turned ON by the turn-ON voltage and electrically couples the first end 234 of the capacitor C to the ground voltage VSS on the source line SL, the controller 102 is configured to sense, e.g., by using the SA 118, a current flowing in the memory cell 200 to detect the datum stored in the memory cell 200.

In FIG. 2B, when the memory cell 200 has been previously programmed to store logic “0,” the insulating material of the capacitor C has been broken down and has become a resistive structure 238, the read voltage applied to the bit line BL causes a current I_{read} to flow through the resistive structure 238 and the turned-ON transistor T to the ground voltage VSS at the source line SL. The SA 118 is configured to sense the current I_{read}. The controller 102 is configured to detect, based on the sensed current I_{read}, that the memory cell 200 stores logic “0.”

In FIG. 2C, when the memory cell 200 has been not previously programmed, the memory cell 200 stores logic “1,” the insulating material of the capacitor C is not yet broken down, and the capacitor C remains a capacitive structure. The read voltage applied to the bit line BL is lower than the breakdown voltage, and causes no current, or a current I_{read} close to zero, to flow through the capacitor C and the turned-ON transistor T to the ground at the source line SL. The SA 118 is configured to sense that there is no current, or a current I_{read} close to zero, that flows through the memory cell 200. Accordingly, the controller 102 is configured to detect that the memory cell 200 stores logic “1.”

In at least one embodiment, the turn-ON voltage in the program operation is the same as the turn-ON voltage in the read operation. Other configurations where different turn-ON voltages are applied in different operations are within the scopes of various embodiments. The read voltage is lower than the program voltage. In at least one embodiment, the program voltage is about 1.2 V or less, the breakdown voltage is about 1.2 V, and the read voltage is about 0.75 V. Other voltage schemes are within the scopes of various embodiments.

In some embodiments, memory cells having the described 1T1C configuration make it possible to achieve one or more advantages over other approaches including, but not limited to, smaller chip area (i.e., the area occupied by the memory cell on a wafer), lower program voltage, lower disturb voltage, improved reliability, enhanced data security, or the like. Furthermore, the present disclosure includes embodiments in which the capacitor is formed in the interconnect layers in order to reduce area and/or cost.

For example, a memory cell in accordance with other approaches that use gate oxide anti-fuses occupies a chip area of about 0.0674 μm², and has a program voltage of about 5 V, a program disturb voltage of about 2.0 V, and a read disturb voltage of about 1.3 V. In contrast, an example memory cell having the 1T1C configuration in accordance with some embodiments of the present disclosure occupies a smaller chip area of about 0.0378 μm² to 0.0674 μm², has a lower program voltage of less than 1.8 V, as well as a lower disturb voltage. The higher program voltage of memory cells that use gate oxide anti-fuses raises reliability concerns. The lower program voltage of memory cells in accordance with some embodiments results in lower stress in the memory cells, and therefore improves reliability. Memory cells in accordance with some embodiments are further applicable to advanced process nodes. In contrast, memory cells that use gate oxide anti-fuses experience scalability and/or manufacturability issues at advanced process nodes.

For another example, a memory cell in accordance with other approaches that use metal fuses (e.g., eFuse) occupies a chip area of about 1.769 μm², and has a program voltage of about 1.8 V. In contrast, an example memory cell having the 1T1C configuration in accordance with some embodiments occupies a smaller chip area of about 0.0378 μm² to 0.0674 μm² which corresponds to a reduction of up to around 90% in chip area. The lower program voltage of memory cells in accordance with some embodiments results in lower stress in the memory cells, and therefore improves reliability over memory cells that use metal fuses. Further, memory cells that use metal fuses have data security concerns which are obviated in memory cells in accordance with some embodiments. Moreover, memory cells in accordance with some embodiments are applicable to advanced process nodes. In contrast, memory cells that use gate oxide anti-fuses or metal fuses experience scalability and/or manufacturability issues at advanced process nodes.

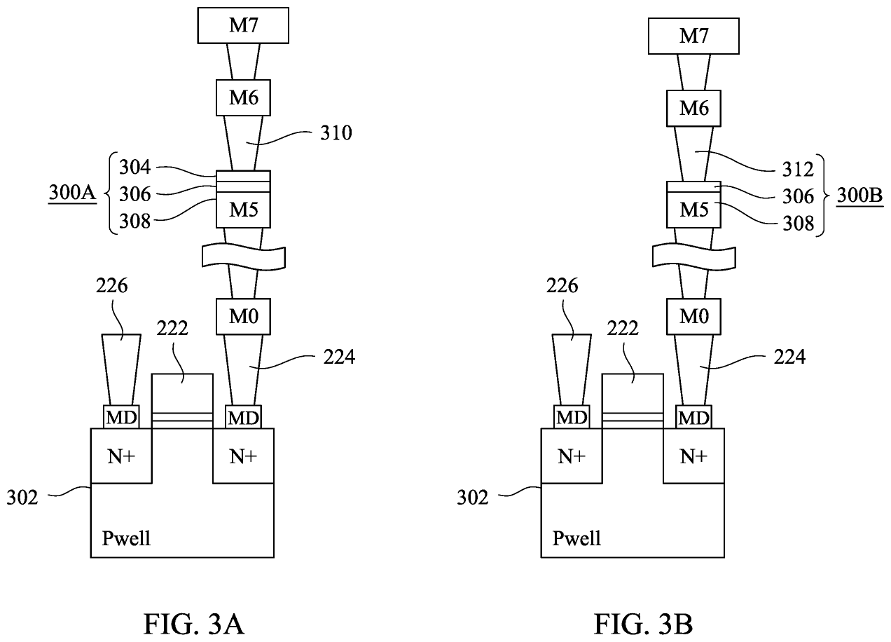

FIGS. 3A and 3B illustrate cross-sectional views of a transistor and a capacitor, in accordance with some embodiments. The transistor and capacitor of FIGS. 3A and 3B may be the transistor T and capacitor C shown in FIGS. 2A-2C, but the present disclosure is not limited thereto. For example, the transistors may be p-type or any other suitable modification may be employed. The transistor 302 in both FIGS. 3A and 3B may include the gate terminal 222, the first electrode 224, and the second electrode 226 which are electrically coupled to the word line, source line, and an electrode of the capacitor C, respectively, as shown in FIG. 2A.

FIG. 3A illustrates a cross-sectional view of a transistor 302 and a capacitor 300A having one structure, in accordance with some embodiments. The capacitor 300A includes a top electrode 304, an insulator 306, and a bottom electrode 308. The top electrode 304 is formed on top of the dielectric insulator 306 and below a via 310. Metal layer (sometimes referred to as a metallization layer) M6 of an interconnect structure formed over the semiconductor devices is shown, but the metal layer formed over the capacitor 300A does not have to be metal layer M6 and can be any other metal layer that is suitable for the memory device. For example, it can be metal layer M1, M2, etc. As discussed above, the insulator 306 may include a high-k dielectric insulator but is not limited thereto. The via 310 is a conductive via that electrically connects the metal layer M6 to the top electrode 304, and the metal layer M6 can be connected to, for example, a bit line. Bottom electrode 308 may be a portion of metal layer M5, or whichever layer is formed below the via 310. For example, if the metal layer formed over the via 310 is metal layer M3, the metal layer that includes the bottom electrode 308 may be metal layer M2.

FIG. 3B illustrates a cross-sectional view of a transistor 302 and a capacitor 300B having another structure, in accordance with some embodiments. The capacitor 300B includes a via 312 as a top electrode, an insulator 306, and a bottom electrode 308. For the capacitor 300B, unlike the capacitor 300A of FIG. 3A, there is no separate top electrode that is formed, and the via 312 may function as the top electrode. By omitting a separately formed top electrode in the capacitor 300B, the fabrication process may reduce costs and materials during fabrication.

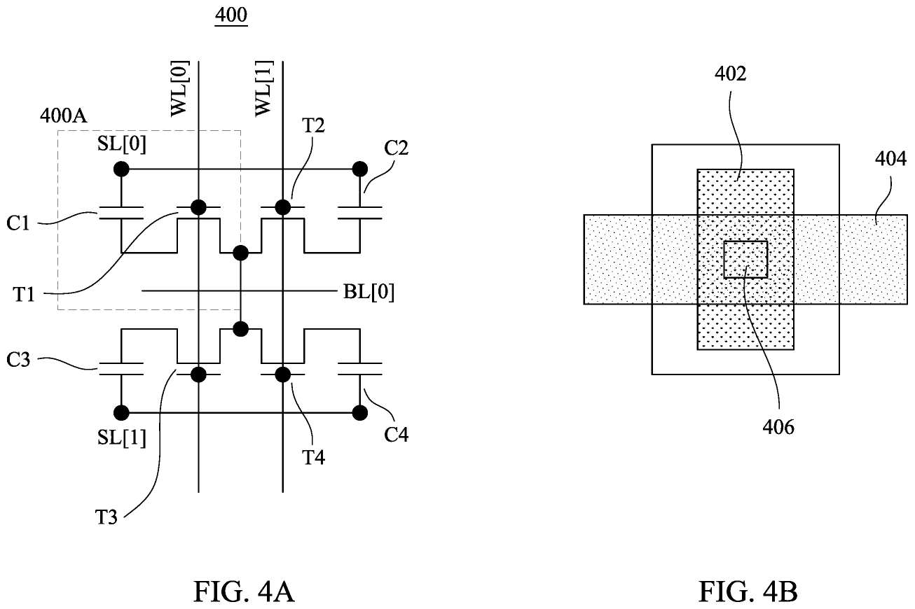

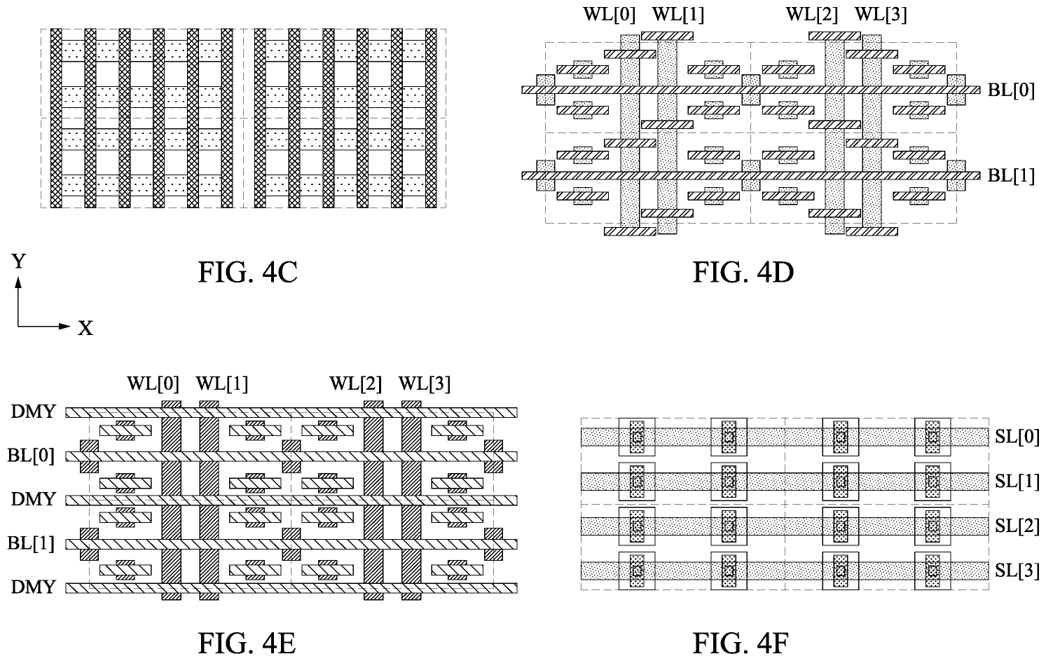

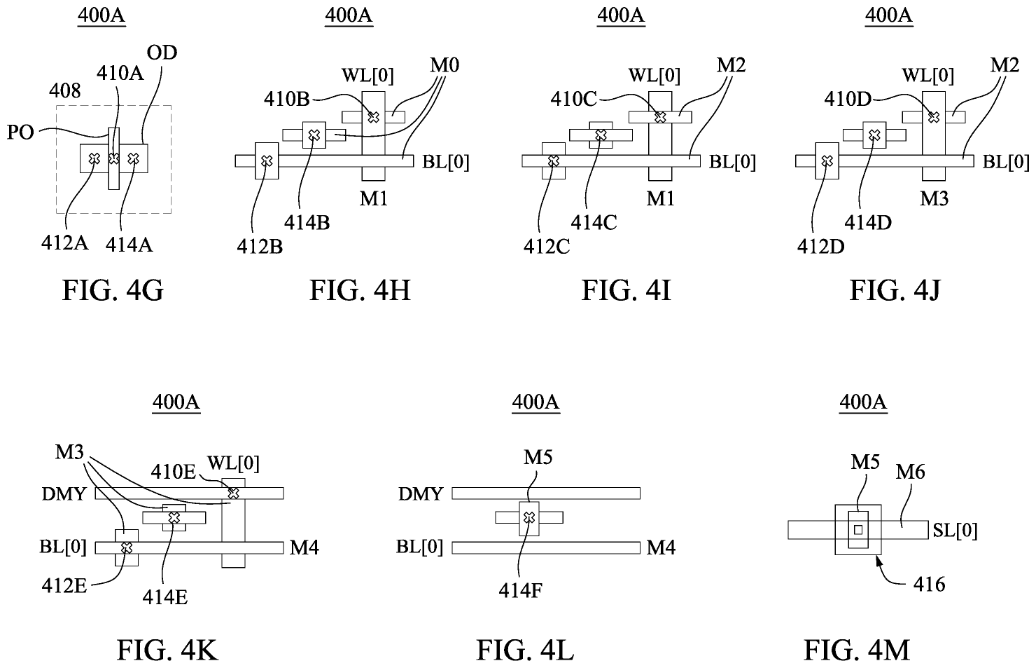

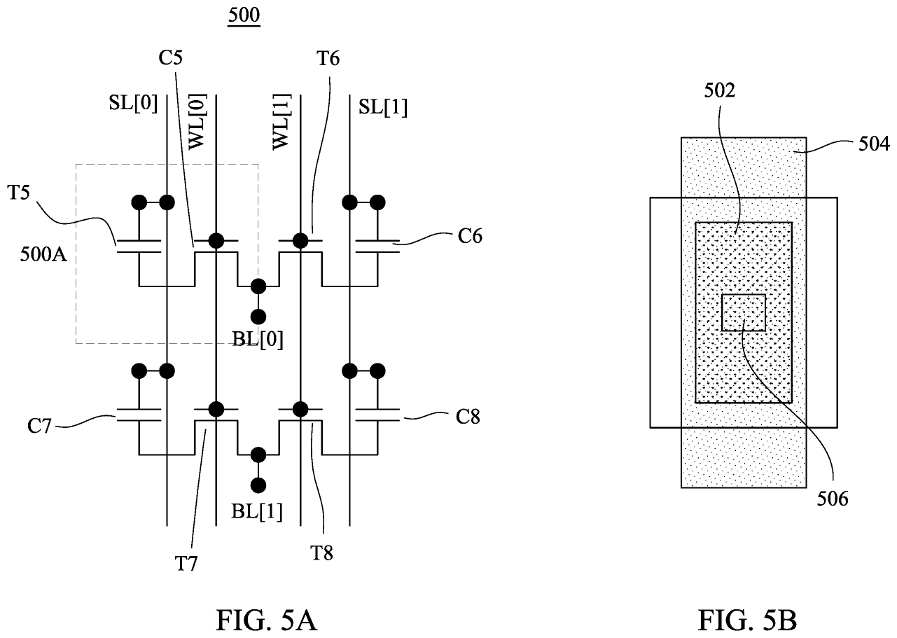

FIG. 4A illustrates a circuit schematic of a memory device 400, in accordance with some embodiments. The memory device 400 includes four memory cells, which can be constituted by four transistors and four capacitors, source lines SL[0] and SL[1], word lines WL[0] and WL[1], and bit line BL[0]. It is understood that the memory device 400 in FIG. 4A is just one example and the memory device 400 can have a variety of different schematics including the ones discussed below. Details of the layout layers of memory cell 400A is illustrated and described with reference to FIGS. 4G-4M.

The memory device 400 includes four 1T1C memory cells which are electrically connected to one another. The cells include cell 1 (i.e., memory cell 400A) including transistor T1 and capacitor C1, cell 2 including transistor T2 and capacitor C2, cell 3 including transistor T3 and capacitor C3, and cell 4 including transistor T4 and capacitor C4. Each of the transistors T1-T4 has a source electrode that is connected to the same bit line BL[0]. Each of the transistors T1 and T3 has a gate electrode that is connected to the word line WL[0], and each of the transistors T2 and T4 has a gate electrode that is connected to the word line WL[1]. Each of the capacitors C1 and C2 has a first electrode (i.e., top electrode) that is connected to the source line SL[0], and each of the capacitors C3 and C4 have a first electrode (i.e., top electrode) that is connected to the source line SL[1]. Each of the capacitors C1-C4 has a second electrode (i.e., bottom electrode) connected to the drain electrode of the transistors T1-T4, respectively. In some embodiments, the first electrodes of the capacitors C1-C4 include the top electrode 304 of capacitor 300A or the via 312 (which functions as a top electrode) of the capacitor 300B, and the second electrodes of the capacitors C1-C4 includes the bottom electrode 308 of the capacitor 300A or capacitor 300B.

Compared to the typical chip area for one-time programmable memory chips having a similar circuit being designed by the existing technologies, the memory cell 400 in some embodiments have approximately a 25% reduction in chip area due to the MIM capacitor being formed in the metal layers over the source/drain electrode of the transistor.

FIG. 4B illustrates a layout of the capacitor C1 for the memory device 400 illustrated in FIG. 4A, in accordance with some embodiments. The capacitor C1 is formed of a bottom electrode 402, an insulator 406, and a top electrode 404. Although the layout only shows several layers, this is for illustrative for purposes only and one of ordinary skill in the art will recognize that there can be additional layers above, below or in between the layers shown.

The layout for several layers of one of the memory cells of the memory device 400 can look like the layout in FIG. 4B. For example, for capacitor C1, the metal layer including the bottom electrode 402 can extend in the y-direction, and the metal layer including the top electrode can extend in the x-direction. At the intersection of the two metal layers and in between the two metal layers, an insulator 406 is formed such that the combination of the metal layers and the insulator 406 forms the capacitor C1 of memory device 400. The bottom and top electrodes 402 and 404 are formed of metal. The bottom electrode 402 can be metal layer M5 in the interconnect structure, as discussed above, but is not limited thereto. The top electrode 404 can be metal layer M6 in the interconnect structure as discussed above but is not limited thereto. For example, the bottom electrode 402 can be metal layer M6, and the top electrode can be metal layer M7.

FIGS. 4C-4F illustrate top-down views of various layers of the memory device 400 of FIG. 4A, in accordance with some embodiments. These layers are illustrated as an example of how the memory device 400 can be layered to form the transistors T1-T4 and an interconnect structure over the transistors to form the capacitors C1-C4. One of ordinary skill will recognize that memory device 400 can be laid out in layers in a different manner so as to form the electrical circuit shown in FIG. 4A. Each of the layouts in FIGS. 4C-4F illustrates four neighboring instances of the memory device 400 of FIG. 4A; in other words, there are 16 memory cells shown. Although not illustrated for clarity, there are a plurality of vias formed either through or in between the layers at different regions of the layers illustrated in FIGS. 4C-4F.

FIG. 4C illustrates the gate layer PO and active layer OD that form portions of the transistors T1-T4, in accordance with some embodiments. The gate layer PO is formed of conductive material such as polysilicon and functions as the gates of the transistors T1-T4. Other conductive materials for the gate layer PO, such as metals, are within the scope of various embodiments. The active layer OD is formed of semiconductor material and may include p-type dopants or n-type dopants. The active layer OD includes the source and drain terminals and the conduction channel of the transistors T1-T4 when the transistors are turned on. The gate layer PO extend in the y-direction, and the active layer OD extend in the x-direction.

FIG. 4D illustrates metal layers M0, M1, and M2, in accordance with some embodiments. The metal layer M0 is the lowermost metal layer of the interconnect structure that is formed over the transistors T1-T4. The metal layer M1 is formed over the metal layer M0, and the metal layer M2 is formed over the metal layer M1. The metal layers M0 and M2 substantially overlap each other in FIG. 4D, but the layers are not limited thereto. The metal layers M0 and M2 extend in the x-direction, and M1 extends in the y-direction.

The metal layers M0 and M2 include the bit lines BL[0], BL[1], BL[2], and BL[3] that carry the corresponding bit line signals. For example, when the bit line driver 116 drives a high voltage on BL[0], a portion of the metal layers M0 and M2 corresponding to the bit line BL[0] will have a high voltage. The metal layer M1 includes the word lines WL[0], WL[1], WL[2], and WL[3] that carry the corresponding word line signals. For example, when the word line driver 112 drives a high voltage to WL[0], the corresponding portion of the metal layer M1 will have a high voltage. The metal layers M0-M2 are also able to have any voltage driven (e.g., low voltage, no voltage) by the corresponding bit line driver 116 or word line driver 112.

FIG. 4E illustrates metal layers M3 and M4, in accordance with some embodiments. The metal layer M3 is formed over the metal layer M2, and the metal layer M4 is formed over the metal layer M3. At least portions of the metal layer M3 and metal layer M1 may be similarly patterned. Therefore, metal layer M1 and metal layer M3 may overlap in portions of the layout. Furthermore, metal layers M1 and M3 can be electrically coupled to each other in portions of the layout. Furthermore, portions of the metal layer M4 and metal layers M0 and M2 may be similarly patterned, and therefore metal layers M0, M2, and M4 may overlap in portions of the layout. Furthermore, the metal layers M0, M2, and M4 may be electrically coupled to each other in portions of the layout.

The metal layer M3 can include word lines WL[0], WL[1], WL[2], and WL[3] that carry the corresponding word line signals. For example, when the word line driver 112 tries to drive a high voltage on WL[0], a portion of the metal layer M3 that corresponds to the word line WL[0] will have a high voltage. The metal layer M4 can include bit lines BL[0], BL[1], BL[2], and BL[3] that carry the corresponding bit line signals. For example, when the bit line driver 116 tries to drive a high voltage on BL[0], portions of the metal layer M3 that correspond to the bit line BL[0] will have a high voltage. The metal layer M4 can also include dummy bit lines DMY. However, these dummy bit lines DMY are not electrically coupled to any of the bit line driver 116, word line driver 112, or source line driver 114 and are therefore not functional. The dummy bit lines DMY may be formed at the edge of the memory device 400.

FIG. 4F illustrates metal layers M5 and M6, in accordance with some embodiments. The metal layer M5 is formed over the metal layer M4, and the metal layer M6 is formed over the metal layer M5. As discussed above, there may be a capacitor formed where metal layer M5 and metal layer M6 overlap. When a dielectric insulator is formed between the metal layers M5 and M6, a MIM capacitor MIM is formed. The MIM capacitors shown in FIG. 4F can be the capacitors C1-C4. In FIG. 4F, there are 16 MIM capacitors shown, but embodiments are not limited thereto and there can be more or fewer than 16 MIM capacitors.

The metal layer M6 can include source lines SL[0], SL[1], SL[2], and SL[3] that carry the corresponding source line signals. For example, when the source line driver 114 drives a high voltage on SL[0], a portion of the metal layer M6 that corresponds to the source line SL[0] will have a high voltage.

FIGS. 4G-4M illustrate various layers of a memory cell 400A of the memory device 400, in accordance with some embodiments. The memory cell 400A includes transistor T1 and capacitor C1 of FIG. 4A, but the present disclosure is not limited thereto and the layouts can be applied to T2 and C2, or T3 and C3, or T4 and C4. FIGS. 4G-4M serve to illustrate the various layers of an example memory cell 400A which include only one transistor T1 and one capacitor C1. The figures illustrate, among other things, the various metal layers, the vias that connect the various metal layers, and their relationships with the bit lines, word lines, and source lines. However, the positions of the vias with respect to one another and the relative positions of the layers may not align vertically. Therefore, for clarity and simplicity purposes, the layers shown in the figures are not meant to overlap one another to show a top-down view of the layout, but one of ordinary skill in the art will recognize that the layers can be rearranged to form a layout of the memory cell.

Referring to FIG. 4G, the gate layer PO and the active layer OD of the memory cell 400A are shown, in accordance with some embodiments. Memory cell 400A includes transistor 408, which can include the transistor T1. A via 410A is formed over the gate layer PO to electrically couple the gate layer PO to a layer above (e.g., word line WL[0]). A via 412A is formed over the active layer OD to electrically couple the active layer OD to a layer above (e.g., bit line BL[0]). A via 414A is formed active layer OD that electrically connects the source terminal of the transistor T1 to a layer above (e.g., metal layer M5) that serves as the bottom electrode of capacitor C1.

Referring to FIG. 4H, metal layers M0 and M1 of the memory cell 400A are illustrated, in accordance with some embodiments. The metal layer M0 extends in the x-direction, and the metal layer M1 extends in y-direction. Vias 410B, 412B, and 414B are formed between the metal layers M0 and M1. Via 410B may overlap with via 410A, via 412B may overlap with via 412A, and via 414B may overlap with via 414A.

The metal layer M0 can function as the bit line BL[0]. In such embodiments, the bit line driver 116 can drive a bit line signal through the bit line BL[0] to the active layer OD through via 412A. Accordingly, the source electrode of the transistor T1 can be electrically connected to the bit line BL[0], as shown in FIG. 4A.

The metal layer M1 can function as the word line WL[0]. The word line driver 112 can drive a word line signal to the gate layer PO through the word line WL[0] to the gate layer PO through vias 410B and 410A. Accordingly, the gate of the transistor T1 can be electrically connected to the word line WL[0], as shown in FIG. 4A.

Referring to FIG. 4I, the metal layers M1 and M2 of the memory cell 400A are illustrated, in accordance with some embodiments. The metal layer M1 extends in the y-direction, and the metal layer M2 extends in the x-direction. Vias 410C, 412C, and 414C are formed between the metal layers M1 and M2. Via 410C may overlap with vias 410A-412B, via 412C may overlap with vias 412A-412B, and via 414C may overlap with vias 414A-412B. As discussed above, metal layer M1 can function as the word line [0].

The metal layer M2 can function as the bit line BL[0]. In such embodiments, the bit line driver 116 can drive a bit line signal through the bit line BL[0] to the active layer OD through vias 412A-412C. Accordingly, the source electrode of the transistor T1 can be electrically connected to the bit line BL[0], as shown in FIG. 4A.

Referring to FIG. 4J, the metal layers M2 and M3 of the memory cell 400A are illustrated, in accordance with some embodiments. The metal layer M2 extends in the x-direction, and the metal layer M3 extends in the y-direction. Vias 410D, 412D, and 414D are formed between the metal layers M2 and M3. Via 410D may overlap with vias 410A-410C, via 412D may overlap with vias 412A-412C, and via 414D may overlap with vias 414A-414C. As discussed above, metal layer M2 can function as the bit line [0].

The metal layer M3 can function as the word line WL[0]. In such embodiments, the word line driver 112 can drive a word line signal through the word line WL[0] to the gate layer PO through vias 410A-410D. Accordingly, the gate of the transistor T1 can be electrically connected to the word line WL[0], as shown in FIG. 4A.

Referring to FIG. 4K, the metal layers M3 and M4 of the memory cell 400A are illustrated, in accordance with some embodiments. The metal layer M3 extends in the y-direction, and the metal layer M4 extends in the x-direction. Vias 410E, 412E, and 414E are formed between the metal layers M3 and M4. Via 410E may overlap with vias 410A-410D, via 412E may overlap with vias 412A-412D, and via 414E may overlap with vias 414A-414D. As discussed above, metal layer M3 can function as the word line WL[0].

The metal layer M4 can function as the bit line BL[0]. In such embodiments, the bit line driver 116 can drive a bit line signal through the bit line BL[0] to the active layer OD through vias 412A-412D. Accordingly, the source electrode of the transistor T1 can be electrically connected to the bit line BL[0], as shown in FIG. 4A.

As discussed with respect to FIG. 4E, a dummy bit line DMY can be formed. Referring to FIG. 4K, the metal layer M4 can include the dummy bit line DMY. However, the dummy bit line DMY does not function as an actual bit line and can be formed, for example, at the edge of a memory array.

Referring to FIG. 4L, the metal layers M4 and M5 of the memory cell 400A are illustrated, in accordance with some embodiments. The metal layer M4 extends in the x-direction, and the metal layer M5 extends in the y-direction. Via 414F is formed between the metal layers M4 and M5. Via 414F may overlap with vias 414A-414E. As discussed above, metal layer M4 can function as the bit line BL[0] or a dummy bit line DMY.

The metal layer M5 can function as the bottom electrode of the capacitor C1. Accordingly, the drain of the transistor T1 can be electrically connected to bottom electrode of the capacitor C1, as shown in FIG. 4A.

Referring to FIG. 4M, the metal layers M5 and M6 of the memory cell 400A are illustrated, in accordance with some embodiments. The metal layer M5 extends in the y-direction, and the metal layer M6 extends in the x-direction. As discussed above, the metal layer M5 can function as the bottom electrode of the capacitor.

The metal layer M6 can function as the top electrode of the capacitor C1. As discussed above, the memory cell 400A includes a MIM capacitor 416 that can include the capacitor C1. Although not shown, a dielectric insulator layer is formed between the metal layers M5 and M6 to form the MIM capacitor 416, and the bottom electrode formed on metal layer M5 is electrically connected to the drain of the transistor 408 through the vias 414A-414E. Accordingly, the MIM capacitor 416 is electrically connected to the transistor 408 of FIG. 4G. Furthermore, although not shown in FIG. 4M, a via can be formed between the metal layers M5 and M6.

The metal layer M6 can function as the source line SL[0]. In such embodiments, the source line driver 114 can drive a source line signal to the metal layer M6 through the source line SL[0] to the top electrode of the MIM capacitor. Accordingly, the top electrode of the capacitor C1 can be electrically connected to the source line SL[0], as shown in FIG. 4A.

Although FIGS. 4G-4M illustrate and describe metal layer M5 including the bottom electrode and the metal layer M6 including the top electrode of the capacitor 408 (and capacitor C1), the embodiments are not limited thereto. As described with reference to FIGS. 3A and 3B, the top electrode can be formed separately above the dielectric insulator and below the metal layer M6 (as illustrated in FIG. 3A), or when there is no separately formed top electrode, the via formed between the dielectric insulator and metal layer M6 may function as a top electrode (as illustrated in FIG. 3B).

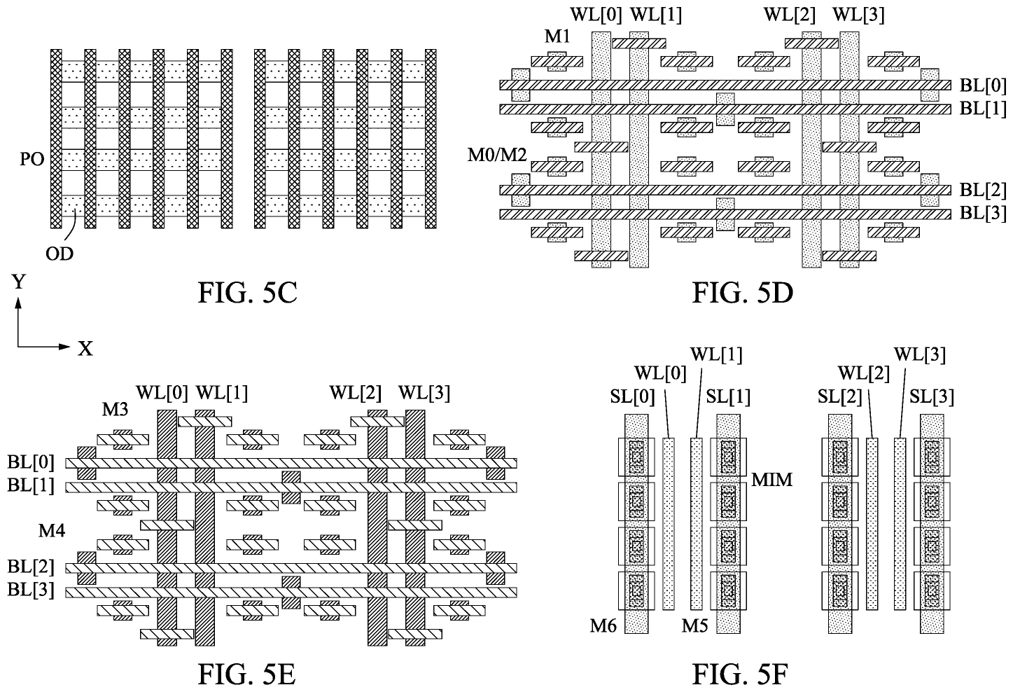

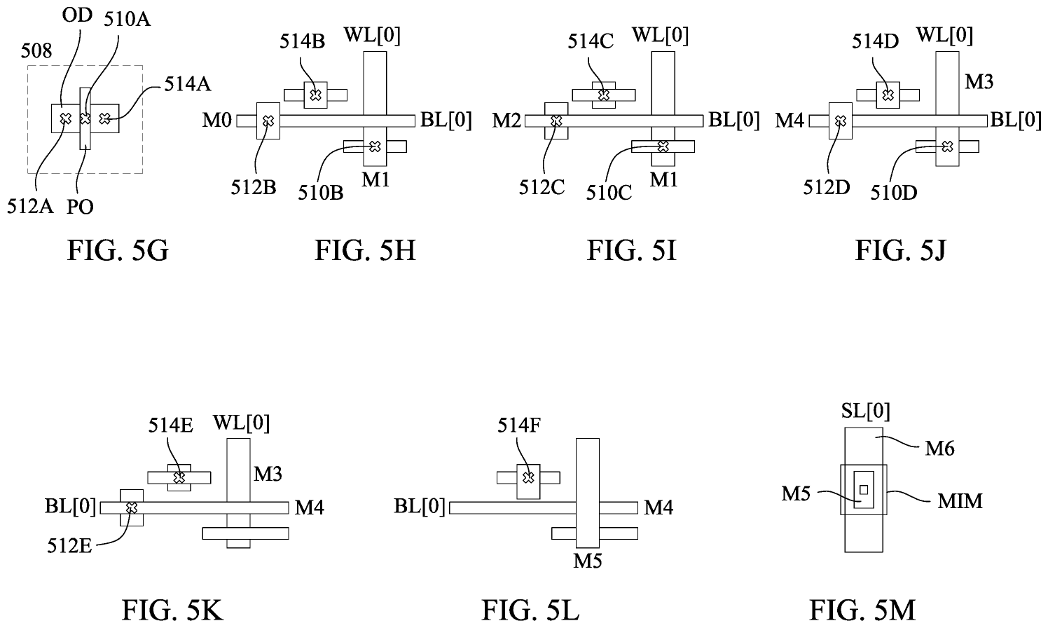

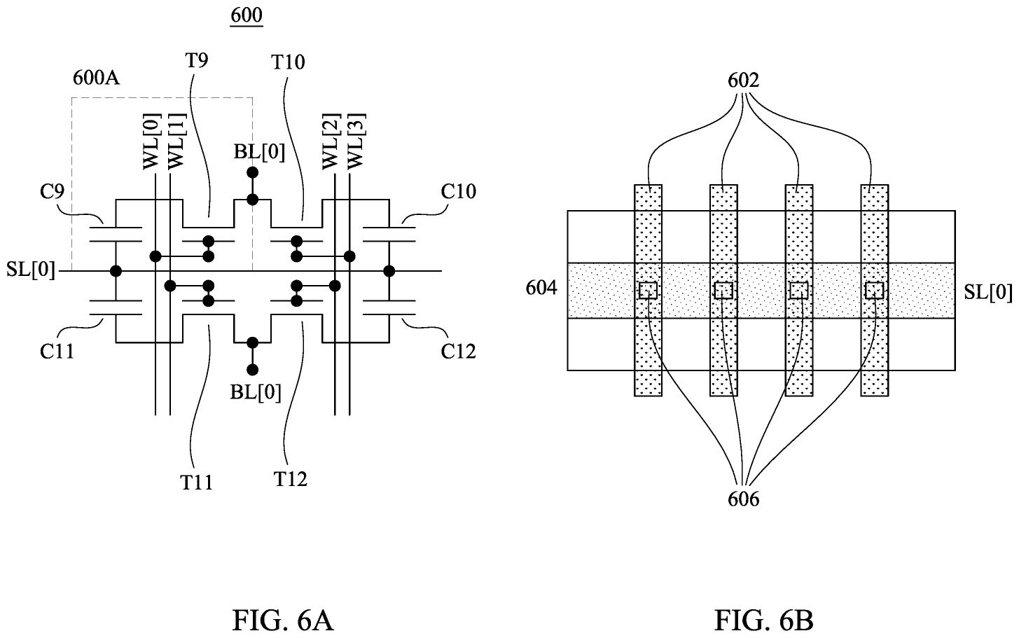

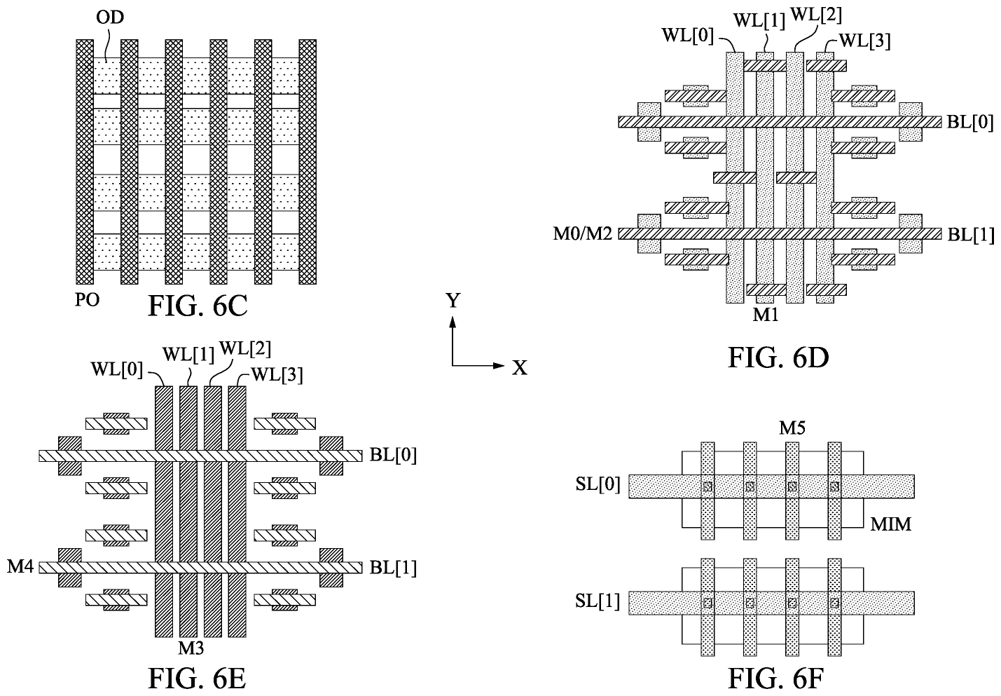

FIG. 5A illustrates a circuit schematic of a memory device 500, in accordance with some embodiments. The memory device 500 includes four memory cells, which can be constituted by four transistors and four capacitors, source lines SL[0] and SL[1], word lines WL[0] and WL[1], and bit lines BL[0] and BL[1]. It is understood that the memory device 500 in FIG. 5A is just one example and the memory device 500 can have a variety of different schematics including the ones discussed below. Details of the layout layers of memory cell 500A is illustrated and described with reference to FIGS. 5G-5M.

The memory device 500 includes four 1T1C memory cells which are electrically connected to one another. The cells include cell 1 (i.e., memory cell 500A) including transistor T5 and capacitor C5, cell 2 including transistor T6 and capacitor C6, cell 3 including transistor T7 and capacitor C7, and cell 4 including transistor T8 and capacitor C8. Each of the transistors T5 and T6 have a source electrode that is connected to the same bit line BL[0], and each of the transistors T7 and T8 have a source electrode that is connected to the same bit line BL[1]. Each of the transistors T5 and T7 has a gate electrode that is connected to the word line WL[0], and each of the transistors T6 and T8 has a gate electrode connected to the word line WL[1]. Each of the capacitors C5 and C7 has a first electrode (i.e., top electrode) connected to the source line SL[0], and each of the capacitors C6 and C8 has a first electrode (i.e., top electrode) connected to the source line SL[1]. Each of the capacitors C5-C8 has a second electrode (i.e., bottom electrode) connected to the drain electrode of the transistors T5-T8, respectively. In some embodiments, the first electrodes of the capacitors C5-C8 include the top electrode 304 of capacitor 300A or the via 312 (which functions as a top electrode) of the capacitor 300B, and the second electrodes of the capacitors C5-C8 includes the bottom electrode 308 of the capacitor 300A or capacitor 300B.

Compared to the typical chip area for one-time programmable memory chips having a similar circuit being designed by the existing technologies, the memory cell 500 in some embodiments have approximately a 15% reduction in chip area due to the MIM capacitor being formed in the metal layers over the source/drain electrode of the transistor.

FIG. 5B illustrates a layout of the capacitor C5 for the memory device 500 illustrated in FIG. 5A, in accordance with some embodiments. The capacitor C5 is formed of a bottom electrode 502, an insulator 506, and a top electrode 504. Although the layout only shows several layers, this is for illustrative for purposes only and one of ordinary skill in the art will recognize that there can be additional layers above, below or in between the layers shown.

The layout for several layers of one of the memory cells of the memory device 500 can look like the layout in FIG. 5B. For example, for capacitor C5, the metal layer including the bottom electrode 502 can extend in the y-direction, and the metal layer including the top electrode can extend in the y-direction. At the intersection of the two metal layers and in between the two metal layers, an insulator 506 is formed such that the combination of the metal layers and the insulator 506 forms the capacitor C5 of memory device 500. The bottom and top electrodes 502 and 504 are formed of metal. The bottom electrode 502 can be metal layer M5 in the interconnect structure, as discussed above, but is not limited thereto. The top electrode 504 can be metal layer M6 in the interconnect structure as discussed above but is not limited thereto. For example, the bottom electrode 502 can be metal layer M6, and the top electrode can be metal layer M7.

FIGS. 5C-5F illustrate top-down views of various layers of the memory device 500 of FIG. 5A, in accordance with some embodiments. These layers are illustrated as an example of how the memory device 500 can be layered to form the transistors T5-T8 and an interconnect structure over the transistors to form the capacitors C5-C8. One of ordinary skill will recognize that memory device 500 can be laid out in layers in a different manner so as to form the electrical circuit shown in FIG. 5A. Each of the layouts in FIGS. 5C-5F illustrates 4 neighboring instances of the memory device 500 of FIG. 5A; in other words, there are 16 memory cells shown. Although not illustrated for clarity, there are a plurality of vias formed either through or in between the layers at different regions of the layers illustrated in FIGS. 5C-5F.

FIG. 5C illustrates the gate layer PO and active layer OD that form portions of the transistors T5-T8, in accordance with some embodiments. The gate layer PO is formed of conductive material such as polysilicon and functions as the gates of the transistors T5-T8. Other conductive materials for the gate layer PO, such as metals, are within the scope of various embodiments. The active layer OD is formed of semiconductor material and may include p-type dopants or n-type dopants. The active layer OD includes the source and drain terminals and the conduction channel of the transistors T5-T8 when the transistors are turned on. The gate layer PO extend in the y-direction, and the active layer OD extend in the x-direction.

FIG. 5D illustrates metal layers M0, M1, and M2, in accordance with some embodiments. The metal layer M0 is the lowermost metal layer of the interconnect structure that is formed over the transistors T5-T8. The metal layer M1 is formed over the metal layer M0, and the metal layer M2 is formed over the metal layer M1. The metal layers M0 and M2 substantially overlap each other in FIG. 5D, but the layers are not limited thereto. The metal layers M0 and M2 extend in the x-direction, and M1 extends in the y-direction.

The metal layers M0 and M2 include the bit lines BL[0], BL[1], BL[2], and BL[3] carry the corresponding bit line signals. For example, when the bit line driver 116 drives a high voltage on BL[0], a portion of the metal layers M0 and M2 corresponding to the bit line BL[0] will have a high voltage. The metal layer M1 includes the word lines WL[0], WL[1], WL[2], and WL[3] that carry the corresponding word line signals. For example, when the word line driver 112 drives a high voltage to WL[0], the corresponding portion of the metal layer M1 will have a high voltage. The metal layers M0-M2 are also able to have any voltage driven (e.g., low voltage, no voltage) by the corresponding bit line driver 116 or word line driver 112.

FIG. 5E illustrates metal layers M3 and M4, in accordance with some embodiments. The metal layer M3 is formed over the metal layer M2, and the metal layer M4 is formed over the metal layer M3. At least portions of the metal layer M3 and metal layer M1 may be similarly patterned. Therefore, metal layer M1 and metal layer M3 may overlap in portions of the layout. Furthermore, metal layers M1 and M3 can be electrically coupled to each other in portions of the layout. Furthermore, portions of the metal layer M4 and metal layers M0 and M2 may be similarly patterned, and therefore metal layers M0, M2, and M4 may overlap in portions of the layout. Furthermore, the metal layers M0, M2, and M4 may be electrically coupled to each other in portions of the layout.

The metal layer M3 can include word lines WL[0], WL[1], WL[2], and WL[3] that carry the corresponding word line signals. For example, when the word line driver 112 tries to drive a high voltage on WL[0], a portion of the metal layer M3 that corresponds to the word line WL[0] will have a high voltage. The metal layer M4 can include bit lines BL[0], BL[1], BL[2], and BL[3] that carry the corresponding bit line signals. For example, when the bit line driver 116 tries to drive a high voltage on BL[0], portions of the metal layer M3 that correspond to the bit line BL[0] will have a high voltage. The metal layer M4 can also include dummy bit lines DMY. However, these dummy bit lines DMY are not electrically coupled to any of the bit line driver 116, word line driver 112, or source line driver 114 and are therefore not functional. The dummy bit lines DMY may be formed at the edge of the memory device 500.

FIG. 5F illustrates metal layers M5 and M6, in accordance with some embodiments. The metal layer M5 is formed over the metal layer M4, and the metal layer M6 is formed over the metal layer M5. As discussed above, there may be a capacitor formed where metal layer M5 and metal layer M6 overlap. When a dielectric insulator is formed between the metal layers M5 and M6, a MIM capacitor MIM is formed. The MIM capacitors shown in FIG. 5F can be the capacitors C5-C8. In FIG. 5F, there are 16 MIM capacitors shown, but embodiments are not limited thereto and there can be more or fewer than 16 MIM capacitors.

The metal layer M6 can include source lines SL[0], SL[1], SL[2], and SL[3] that carry the corresponding source line signals. For example, when the source line driver 114 drives a high voltage on SL[0], a portion of the metal layer M6 that corresponds to the source line SL[0] will have a high voltage.

FIGS. 5G-5M illustrate various layers of a memory cell 500A of the memory device 500, in accordance with some embodiments. The memory cell 500A includes transistor T5 and capacitor C5 of FIG. 5A, but the present disclosure is not limited thereto and the layouts can be applied to T6 and C6, or T7 and C7, or T8 and C8. FIGS. 5G-5M serve to illustrate the various layers of an example memory cell 500A which include only one transistor T5 and one capacitor C5. The figures illustrate, among other things, the various metal layers, the vias that connect the various metal layers, and their relationships with the bit lines, word lines, and source lines. In However, the positions of the vias with respect to one another and the relative positions of the layers may not align vertically. Therefore, for clarity and simplicity purposes, the layers shown in the figures are not meant to overlap one another to show a top-down view of the layout, but one of ordinary skill in the art will recognize that the layers can be rearranged to form a layout of the memory cell.

Referring to FIG. 5G, the gate layer PO and the active layer OD of the memory cell 500A are shown, in accordance with some embodiments. Memory cell 500A includes transistor 508, which can include the transistor T5. A via 510A is formed over the gate layer PO to electrically connect the gate layer PO to a layer above (e.g., word line WL[0]). A via 512A is formed over the active layer OD to electrically connect the active layer OD to a layer above (e.g., bit line BL[0]). A via 514A is formed active layer OD that electrically connects the source terminal of the transistor T5 to a layer above (e.g., metal layer M5) that serves as the bottom electrode of capacitor C5.

Referring to FIG. 5H, metal layers M0 and M1 of the memory cell 500A are illustrated, in accordance with some embodiments. The metal layer M0 extends in the x-direction, and the metal layer M1 extends in y-direction. Vias 510B, 512B, and 514B are formed between the metal layers M0 and M1. Via 510B may overlap with via 510A, via 512B may overlap with via 512A, and via 514B may overlap with via 514A.

The metal layer M0 can function as the bit line BL[0]. In such embodiments, the bit line driver 116 can drive a bit line signal through the bit line BL[0] to the active layer OD through via 512A. Accordingly, the source electrode of the transistor T5 can be electrically connected to the bit line BL[0], as shown in FIG. 5A.

The metal layer M1 can function as the word line WL[0]. The word line driver 112 can drive a word line signal to the gate layer PO through the word line WL[0] to the gate layer PO through vias 510B and 510A. Accordingly, the gate of the transistor T5 can be electrically connected to the word line WL[0], as shown in FIG. 5A.

Referring to FIG. 5I, the metal layers M1 and M2 of the memory cell 500A are illustrated, in accordance with some embodiments. The metal layer M1 extends in the y-direction, and the metal layer M2 extends in the x-direction. Vias 510C, 512C, and 514C are formed between the metal layers M1 and M2. Via 510C may overlap with vias 510A-512B, via 512C may overlap with vias 512A-512B, and via 514C may overlap with vias 514A-512B. As discussed above, metal layer M1 can function as the word line [0].

The metal layer M2 can function as the bit line BL[0]. In such embodiments, the bit line driver 116 can drive a bit line signal through the bit line BL[0] to the active layer OD through vias 512A-512C. Accordingly, the source electrode of the transistor T5 can be electrically connected to the bit line BL[0], as shown in FIG. 5A.

Referring to FIG. 5J, the metal layers M2 and M3 of the memory cell 500A are illustrated, in accordance with some embodiments. The metal layer M2 extends in the x-direction, and the metal layer M3 extends in the y-direction. Vias 510D, 512D, and 514D are formed between the metal layers M2 and M3. Via 510D may overlap with vias 510A-510C, via 512D may overlap with vias 512A-512C, and via 514D may overlap with vias 514A-514C. As discussed above, metal layer M2 can function as the bit line [0].

The metal layer M3 can function as the word line WL[0]. In such embodiments, the word line driver 112 can drive a word line signal through the word line WL[0] to the gate layer PO through vias 510A-510D. Accordingly, the gate of the transistor T5 can be electrically connected to the word line WL[0], as shown in FIG. 5A.

Referring to FIG. 5K, the metal layers M3 and M4 of the memory cell 500A are illustrated, in accordance with some embodiments. The metal layer M3 extends in the y-direction, and the metal layer M4 extends in the x-direction. Vias 512E and 514E are formed between the metal layers M3 and M4. Via 512E may overlap with vias 512A-512D, and via 514E may overlap with vias 514A-514D. As discussed above, metal layer M3 can function as the word line WL[0].

The metal layer M4 can function as the bit line BL[0]. In such embodiments, the bit line driver 116 can drive a bit line signal through the bit line BL[0] to the active layer OD through vias 512A-512D. Accordingly, the source electrode of the transistor T5 can be electrically connected to the bit line BL[0], as shown in FIG. 5A.

As discussed with respect to FIG. 5E, a dummy bit line DMY can be formed. Referring to FIG. 5K, the metal layer M4 can include the dummy bit line DMY. However, the dummy bit line DMY does not function as an actual bit line and can be formed, for example, at the edge of a memory array.

Referring to FIG. 5L, the metal layers M4 and M5 of the memory cell 500A are illustrated, in accordance with some embodiments. The metal layer M4 extends in the x-direction, and the metal layer M5 extends in the y-direction. Via 514F is formed between the metal layers M4 and M5. Via 514F may overlap with vias 514A-514E. As discussed above, metal layer M4 can function as the bit line BL[0] or a dummy bit line DMY.

The metal layer M5 can function as the bottom electrode of the capacitor C5. Accordingly, the drain of the transistor T5 can be electrically connected to bottom electrode of the capacitor C5, as shown in FIG. 5A.

Referring to FIG. 5M, the metal layers M5 and M6 of the memory cell 500A are illustrated, in accordance with some embodiments. The metal layer M5 extends in the y-direction, and the metal layer M6 extends in the y-direction. As discussed above, the metal layer M5 can function as the bottom electrode of the capacitor.

The metal layer M6 can function as the top electrode of the capacitor C5. As discussed above, the memory cell 500A includes a MIM capacitor 516 that can include the capacitor C5. Although not shown, a dielectric insulator layer is formed between the metal layers M5 and M6 to form the MIM capacitor 516, and the bottom electrode formed on metal layer M5 is electrically connected to the drain of the transistor 508 through the vias 514A-514E. Accordingly, the MIM capacitor 516 is electrically connected to the transistor 508 of FIG. 5G. Furthermore, although not shown in FIG. 5M, a via can be formed between the metal layers M5 and M6.

The metal layer M6 can function as the source line SL[0]. In such embodiments, the source line driver 114 can drive a source line signal to the metal layer M6 through the source line SL[0] to the top electrode of the MIM capacitor. Accordingly, the top electrode of the capacitor C5 can be electrically connected to the source line SL[0], as shown in FIG. 5A.

Although FIGS. 5G-5M illustrate and describe metal layer M5 including the bottom electrode and the metal layer M6 including the top electrode of the capacitor 508 (and capacitor C5), the embodiments are not limited thereto. As described with reference to FIGS. 3A and 3B, the top electrode can be formed separately above the dielectric insulator and below the metal layer M6 (as illustrated in FIG. 3A), or when there is no separately formed top electrode, the via formed between the dielectric insulator and metal layer M6 may function as a top electrode (as illustrated in FIG. 3B).

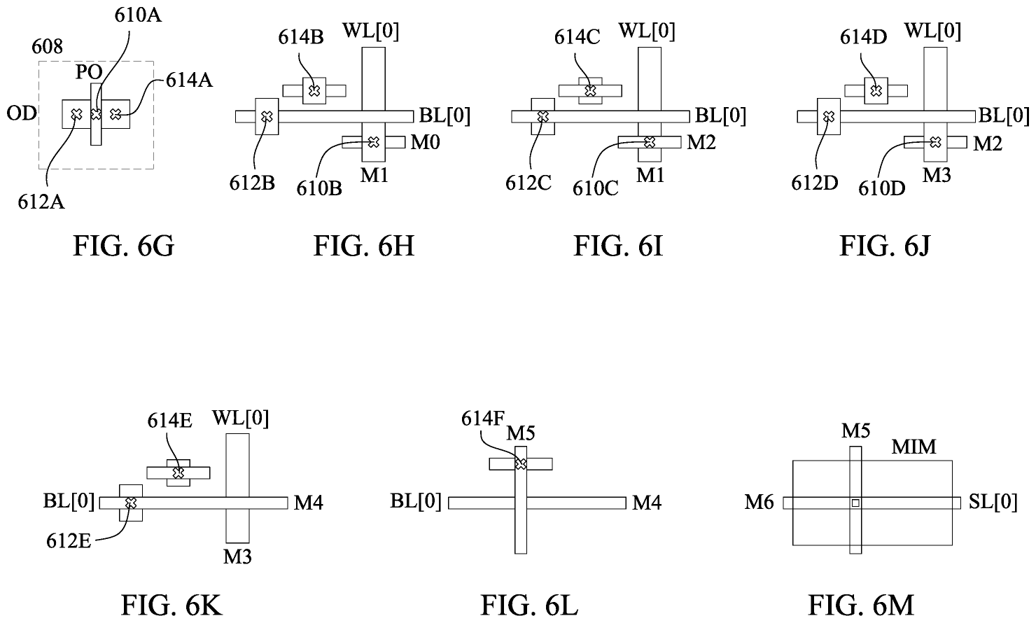

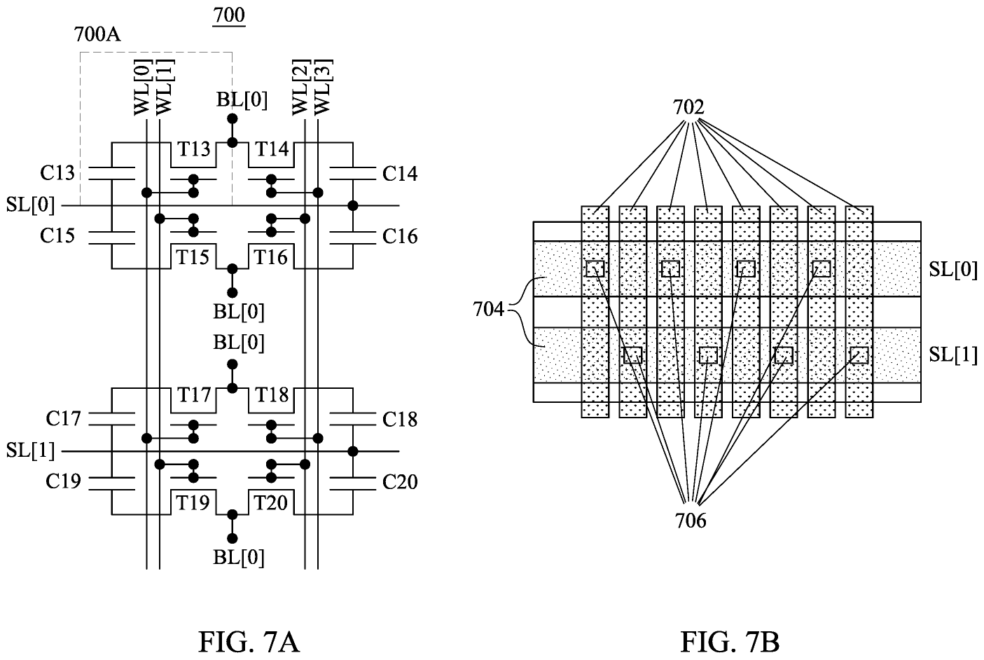

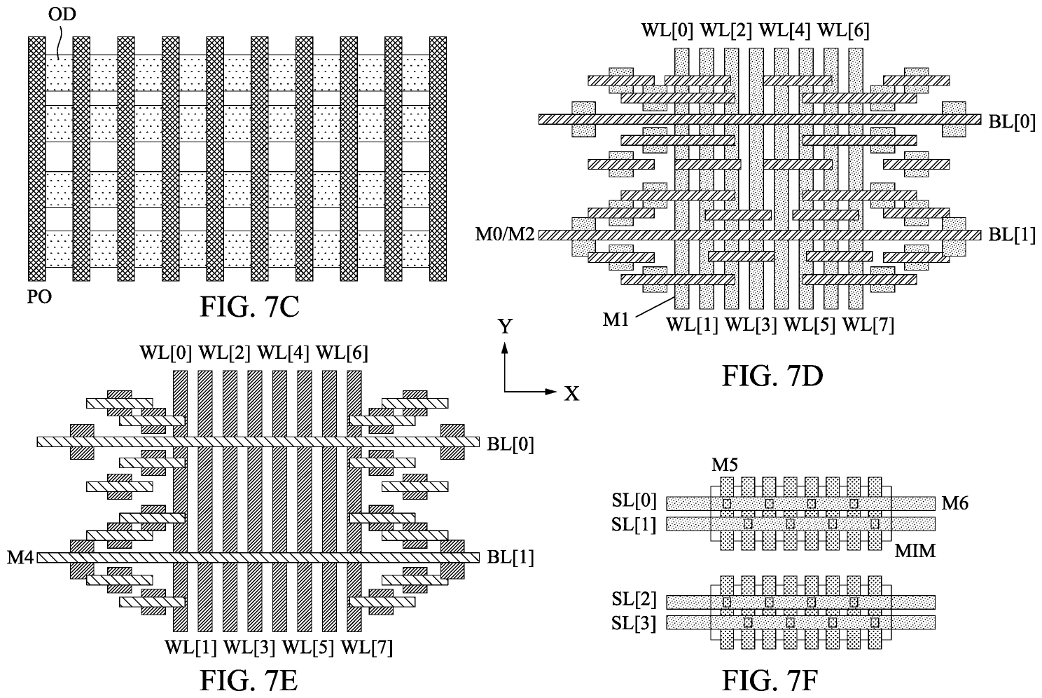

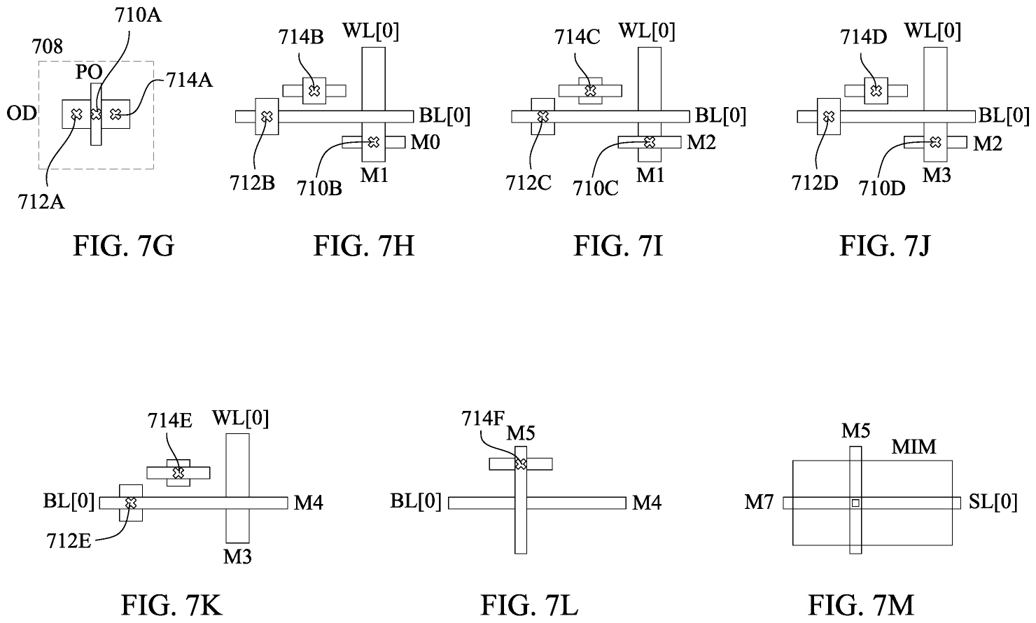

FIG. 6A illustrates a circuit schematic of a memory device 600, in accordance with some embodiments. The memory device 600 includes four memory cells, which can be constituted by four transistors and four capacitors, source line SL[0], word lines WL[0], WL[1], WL[2], and WL[3], and bit line BL[0]. It is understood that the memory device 600 in FIG. 6A is just one example and the memory device 600 can have a variety of different schematics including the ones discussed below. Details of the layout layers of memory cell 600A is illustrated and described with reference to FIGS. 6G-6M.

The memory device 600 includes four 1T1C memory cells which are electrically connected to one another. The cells include cell 1 (i.e., memory cell 600A) including transistor T9 and capacitor C9, cell 2 including transistor T10 and capacitor C10, cell 3 including transistor T11 and capacitor C11, and cell 4 including transistor T12 and capacitor C12. Each of the transistors T9-T12 have a source electrode that is connected to the same bit line BL[0]. Each of the transistors T9-T12 has a gate electrode that is connected to the word lines WL[0]-WL[3], respectively. Each of the capacitors C9-C12 has a first electrode (i.e., top electrode) connected to the source line SL[0]. Each of the capacitors C9-C12 has a second electrode (i.e., bottom electrode) connected to the drain electrode of the transistors T9-T12, respectively. In some embodiments, the first electrodes of the capacitors C9-C12 include the top electrode 304 of capacitor 300A or the via 312 (which functions as a top electrode) of the capacitor 300B, and the second electrodes of the capacitors C9-C12 includes the bottom electrode 308 of the capacitor 300A or capacitor 300B.

Compared to the typical cost of fabricating one-time programmable memory chips having a similar circuit being designed by the existing technologies, the memory cell 600 in some embodiments have approximately a lower cost due to the MIM capacitor being formed in the metal layers over the source/drain electrode of the transistor.

FIG. 6B illustrates a layout of the capacitors C9-C12 for the memory device 600 illustrated in FIG. 6A, in accordance with some embodiments. Each of the capacitors C9 is formed of a bottom electrode 602, an insulator 606, and a top electrode 604. Although the layout only shows several layers, this is for illustrative for purposes only and one of ordinary skill in the art will recognize that there can be additional layers above, below or in between the layers shown.

The layout for several layers of one of the memory cells of the memory device 600 can look like the layout in FIG. 6B. For example, for each of the capacitors C9-C12, the metal layer including the bottom electrode 602 can extend in the y-direction, and the metal layer including the top electrode can extend in the x-direction. Furthermore, even though there are four separate capacitors C9-C12, only one metal layer is formed that form the top electrode 604 for each of the capacitors C9-C12. At the intersection of the two metal layers and in between the two metal layers, an insulator 606 is formed such that the combination of the metal layers and the insulator 606 forms the capacitors C9-C12. The bottom and top electrodes 602 and 604 are formed of metal. The bottom electrode 602 can be metal layer M5 in the interconnect structure, as discussed above, but is not limited thereto. The top electrode 604 can be metal layer M6 in the interconnect structure as discussed above but is not limited thereto. For example, the bottom electrode 602 can be metal layer M6, and the top electrode can be metal layer M7.

FIGS. 6C-6F illustrate top-down views of various layers of the memory device 600 of FIG. 6A, in accordance with some embodiments. These layers are illustrated as an example of how the memory device 600 can be layered to form the transistors T9-T12 and an interconnect structure over the transistors to form the capacitors C9-C12. One of ordinary skill will recognize that memory device 600 can be laid out in layers in a different manner so as to form the electrical circuit shown in FIG. 6A. Each of the layouts in FIGS. 6C-6F illustrates 2 neighboring instances of the memory device 600 of FIG. 6A; in other words, there are 8 memory cells shown. Although not illustrated for clarity, there are a plurality of vias formed either through or in between the layers at different regions of the layers illustrated in FIGS. 6C-6F.

FIG. 6C illustrates the gate layer PO and active layer OD that form portions of the transistors T9-T12, in accordance with some embodiments. The gate layer PO is formed of conductive material such as polysilicon and functions as the gates of the transistors T9-T12. Other conductive materials for the gate layer PO, such as metals, are within the scope of various embodiments. The active layer OD is formed of semiconductor material and may include p-type dopants or n-type dopants. The active layer OD includes the source and drain terminals and the conduction channel of the transistors T9-T12 when the transistors are turned on. The gate layer PO extend in the y-direction, and the active layer OD extend in the x-direction.

FIG. 6D illustrates metal layers M0, M1, and M2, in accordance with some embodiments. The metal layer M0 is the lowermost metal layer of the interconnect structure that is formed over the transistors T9-T12. The metal layer M1 is formed over the metal layer M0, and the metal layer M2 is formed over the metal layer M1. The metal layers M0 and M2 substantially overlap each other in FIG. 6D, but the layers are not limited thereto. The metal layers M0 and M2 extend in the x-direction, and M1 extends in the y-direction.

The metal layers M0 and M2 include the bit lines BL[0] and BL[1] carry the corresponding bit line signals. For example, when the bit line driver 116 drives a high voltage on BL[0], a portion of the metal layers M0 and M2 corresponding to the bit line BL[0] will have a high voltage. The metal layer M1 includes the word lines WL[0], WL[1], WL[2], and WL[3] that carry the corresponding word line signals. For example, when the word line driver 112 drives a high voltage to WL[0], the corresponding portion of the metal layer M1 will have a high voltage. The metal layers M0-M2 are also able to have any voltage driven (e.g., low voltage, no voltage) by the corresponding bit line driver 116 or word line driver 112.

FIG. 6E illustrates metal layers M3 and M4, in accordance with some embodiments. The metal layer M3 is formed over the metal layer M2, and the metal layer M4 is formed over the metal layer M3. At least portions of the metal layer M3 and metal layer M1 may be similarly patterned. Therefore, metal layer M1 and metal layer M3 may overlap in portions of the layout. Furthermore, metal layers M1 and M3 can be electrically coupled to each other in portions of the layout. Furthermore, portions of the metal layer M4 and metal layers M0 and M2 may be similarly patterned, and therefore metal layers M0, M2, and M4 may overlap in portions of the layout. Furthermore, the metal layers M0, M2, and M4 may be electrically coupled to each other in portions of the layout.

The metal layer M3 can include word lines WL[0], WL[1], WL[2], and WL[3] that carry the corresponding word line signals. For example, when the word line driver 112 tries to drive a high voltage on WL[0], a portion of the metal layer M3 that corresponds to the word line WL[0] will have a high voltage. The metal layer M4 can include bit lines BL[0] and BL[1] that carry the corresponding bit line signals. For example, when the bit line driver 116 tries to drive a high voltage on BL[0], portions of the metal layer M3 that correspond to the bit line BL[0] will have a high voltage. The metal layer M4 can also include dummy bit lines DMY. However, these dummy bit lines DMY are not electrically coupled to any of the bit line driver 116, word line driver 112, or source line driver 114 and are therefore not functional. The dummy bit lines DMY may be formed at the edge of the memory device 600.

FIG. 6F illustrates metal layers M5 and M6, in accordance with some embodiments. The metal layer M5 is formed over the metal layer M4, and the metal layer M6 is formed over the metal layer M5. As discussed above, there may be a capacitor formed where metal layer M5 and metal layer M6 overlap. When a dielectric insulator is formed between the metal layers M5 and M6, a MIM capacitor MIM is formed. The MIM capacitors shown in FIG. 6F can be the capacitors C9-C12. In FIG. 6F, there are 16 MIM capacitors shown, but embodiments are not limited thereto and there can be more or fewer than 16 MIM capacitors.

The metal layer M6 can include source lines SL[0] and SL[1] that carry the corresponding source line signals. For example, when the source line driver 114 drives a high voltage on SL[0], a portion of the metal layer M6 that corresponds to the source line SL[0] will have a high voltage.

FIGS. 6G-6M illustrate various layers of a memory cell 600A of the memory device 600, in accordance with some embodiments. The memory cell 600A includes transistor T9 and capacitor C9 of FIG. 6A, but the present disclosure is not limited thereto and the layouts can be applied to T10 and C10, or T11 and C11, or T12 and C12. FIGS. 6G-6M serve to illustrate the various layers of an example memory cell 600A which include only one transistor T9 and one capacitor C9. The figures illustrate, among other things, the various metal layers, the vias that connect the various metal layers, and their relationships with the bit lines, word lines, and source lines. In However, the positions of the vias with respect to one another and the relative positions of the layers may not align vertically. Therefore, for clarity and simplicity purposes, the layers shown in the figures are not meant to overlap one another to show a top-down view of the layout, but one of ordinary skill in the art will recognize that the layers can be rearranged to form a layout of the memory cell.

Referring to FIG. 6G, the gate layer PO and the active layer OD of the memory cell 600A are shown, in accordance with some embodiments. Memory cell 600A includes transistor 608, which can include the transistor T9. A via 610A is formed over the gate layer PO to electrically connect the gate layer PO to a layer above (e.g., word line WL[0]). A via 612A is formed over the active layer OD to electrically connect the active layer OD to a layer above (e.g., bit line BL[0]). A via 614A is formed active layer OD that electrically connects the source terminal of the transistor T9 to a layer above (e.g., metal layer M5) that serves as the bottom electrode of capacitor C9.

Referring to FIG. 6H, metal layers M0 and M1 of the memory cell 600A are illustrated, in accordance with some embodiments. The metal layer M0 extends in the x-direction, and the metal layer M1 extends in y-direction. Vias 610B, 612B, and 614B are formed between the metal layers M0 and M1. Via 610B may overlap with via 610A, via 612B may overlap with via 612A, and via 614B may overlap with via 614A.

The metal layer M0 can function as the bit line BL[0]. In such embodiments, the bit line driver 116 can drive a bit line signal through the bit line BL[0] to the active layer OD through via 612A. Accordingly, the source electrode of the transistor T9 can be electrically connected to the bit line BL[0], as shown in FIG. 6A.

The metal layer M1 can function as the word line WL[0]. The word line driver 112 can drive a word line signal to the gate layer PO through the word line WL[0] to the gate layer PO through vias 610B and 610A. Accordingly, the gate of the transistor T9 can be electrically connected to the word line WL[0], as shown in FIG. 6A.

Referring to FIG. 6I, the metal layers M1 and M2 of the memory cell 600A are illustrated, in accordance with some embodiments. The metal layer M1 extends in the y-direction, and the metal layer M2 extends in the x-direction. Vias 610C, 612C, and 614C are formed between the metal layers M1 and M2. Via 610C may overlap with vias 610A-612B, via 612C may overlap with vias 612A-612B, and via 614C may overlap with vias 614A-612B. As discussed above, metal layer M1 can function as the word line WL[0].

The metal layer M2 can function as the bit line BL[0]. In such embodiments, the bit line driver 116 can drive a bit line signal through the bit line BL[0] to the active layer OD through vias 612A-612C. Accordingly, the source electrode of the transistor T9 can be electrically connected to the bit line BL[0], as shown in FIG. 6A.

Referring to FIG. 6J, the metal layers M2 and M3 of the memory cell 600A are illustrated, in accordance with some embodiments. The metal layer M2 extends in the x-direction, and the metal layer M3 extends in the y-direction. Vias 610D, 612D, and 614D are formed between the metal layers M2 and M3. Via 610D may overlap with vias 610A-610C, via 612D may overlap with vias 612A-612C, and via 614D may overlap with vias 614A-614C. As discussed above, metal layer M2 can function as the bit line [0].

The metal layer M3 can function as the word line WL[0]. In such embodiments, the word line driver 112 can drive a word line signal through the word line WL[0] to the gate layer PO through vias 610A-610D. Accordingly, the gate of the transistor T9 can be electrically connected to the word line WL[0], as shown in FIG. 6A.

Referring to FIG. 6K, the metal layers M3 and M4 of the memory cell 600A are illustrated, in accordance with some embodiments. The metal layer M3 extends in the y-direction, and the metal layer M4 extends in the x-direction. Vias 612E and 614E are formed between the metal layers M3 and M4. Via 612E may overlap with vias 612A-612D, and via 614E may overlap with vias 614A-614D. As discussed above, metal layer M3 can function as the word line [0].

The metal layer M4 can function as the bit line BL[0]. In such embodiments, the bit line driver 116 can drive a bit line signal through the bit line BL[0] to the active layer OD through vias 612A-612D. Accordingly, the source electrode of the transistor T9 can be electrically connected to the bit line BL[0], as shown in FIG. 6A.

As discussed with respect to FIG. 6E, a dummy bit line DMY can be formed. Referring to FIG. 6K, the metal layer M4 can include the dummy bit line DMY. However, the dummy bit line DMY does not function as an actual bit line and can be formed, for example, at the edge of a memory array.

Referring to FIG. 6L, the metal layers M4 and M5 of the memory cell 600A are illustrated, in accordance with some embodiments. The metal layer M4 extends in the x-direction, and the metal layer M5 extends in the y-direction. Via 614F is formed between the metal layers M4 and M5. Via 614F may overlap with vias 614A-614E. As discussed above, metal layer M4 can function as the bit line BL[0] or a dummy bit line DMY.

The metal layer M5 can function as the bottom electrode of the capacitor C9. Accordingly, the drain of the transistor T9 can be electrically connected to bottom electrode of the capacitor C9, as shown in FIG. 6A.

Referring to FIG. 6M, the metal layers M5 and M6 of the memory cell 600A are illustrated, in accordance with some embodiments. The metal layer M5 extends in the y-direction, and the metal layer M6 extends in the x-direction. As discussed above, the metal layer M5 can function as the bottom electrode of the capacitor.

The metal layer M6 can function as the top electrode of the capacitor C9. As discussed above, the memory cell 600A includes a MIM capacitor 616 that can include the capacitor C9. Although not shown, a dielectric insulator layer is formed between the metal layers M5 and M6 to form the MIM capacitor 616, and the bottom electrode formed on metal layer M5 is electrically connected to the drain of the transistor 608 through the vias 614A-614E. Accordingly, the MIM capacitor 616 is electrically connected to the transistor 608 of FIG. 6G. Furthermore, although not shown in FIG. 6M, a via can be formed between the metal layers M5 and M6.

The metal layer M6 can function as the source line SL[0]. In such embodiments, the source line driver 114 can drive a source line signal to the metal layer M6 through the source line SL[0] to the top electrode of the MIM capacitor. Accordingly, the top electrode of the capacitor C9 can be electrically connected to the source line SL[0], as shown in FIG. 6A.

Although FIGS. 6G-6M illustrate and describe metal layer M5 including the bottom electrode and the metal layer M6 including the top electrode of the capacitor 608 (and capacitor C9), the embodiments are not limited thereto. As described with reference to FIGS. 3A and 3B, the top electrode can be formed separately above the dielectric insulator and below the metal layer M6 (as illustrated in FIG. 3A), or when there is no separately formed top electrode, the via formed between the dielectric insulator and metal layer M6 may function as a top electrode (as illustrated in FIG. 3B).

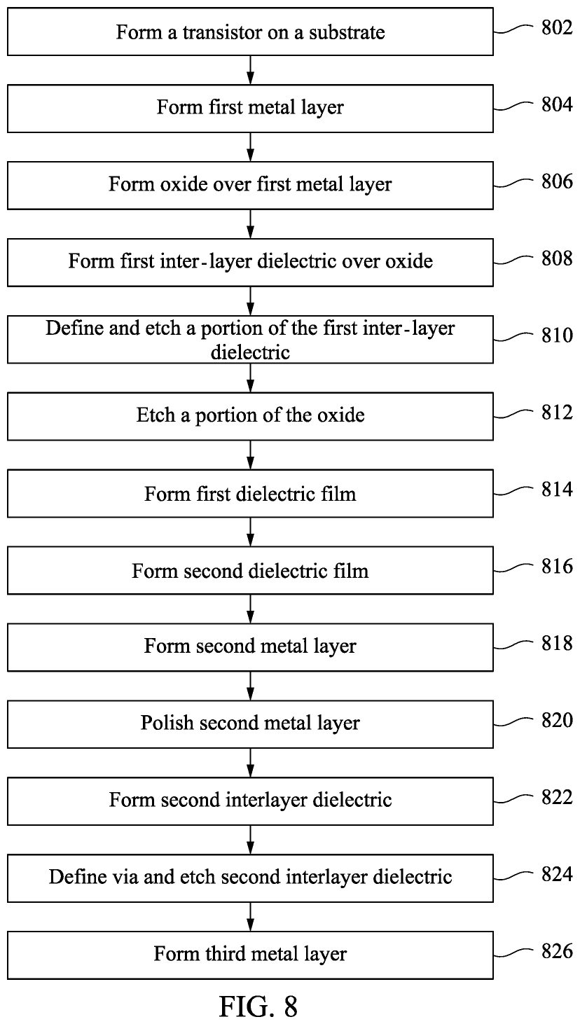

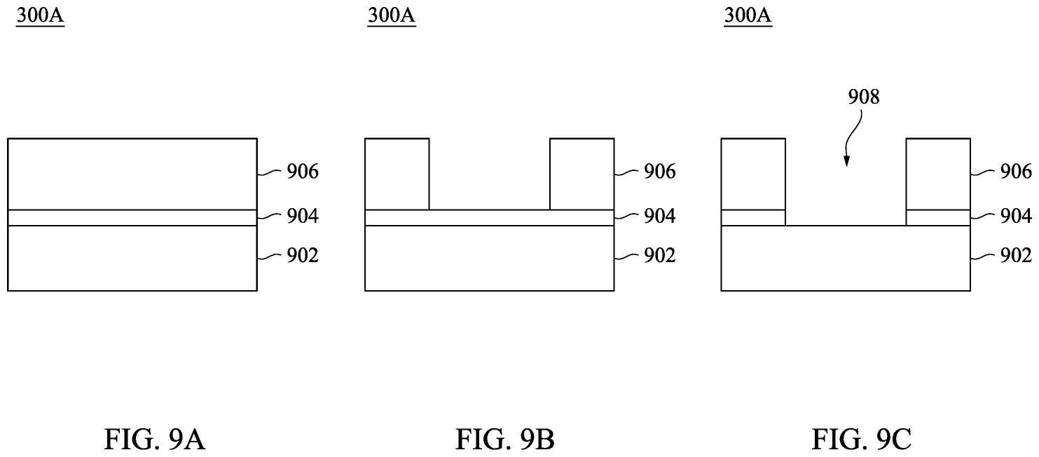

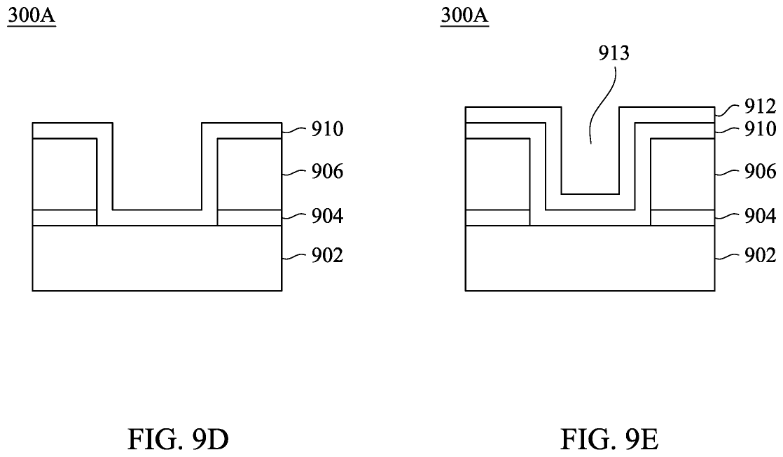

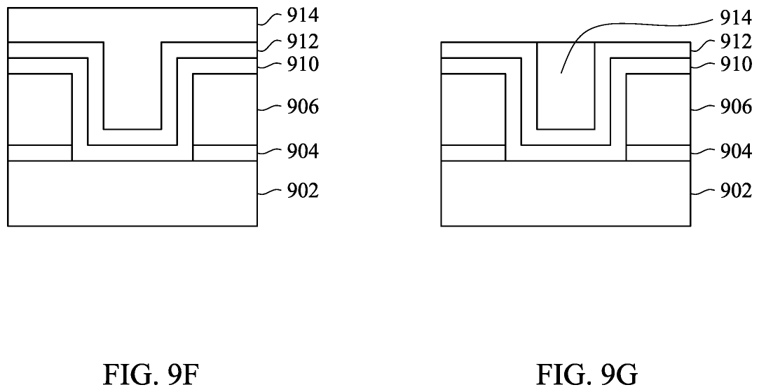

FIG. 7A illustrates a circuit schematic of a memory device 700, in accordance with some embodiments. The memory device 700 includes eight memory cells, which can be constituted by eight transistors and eight capacitors, source lines SL[0] and SL[1], word lines WL[0], WL[1], WL[2], and WL[3], and bit line BL[0]. It is understood that the memory device 700 in FIG. 7A is just one example and the memory device 700 can have a variety of different schematics including the ones discussed below. Details of the layout layers of memory cell 700A is illustrated and described with reference to FIGS. 7G-7M.

The memory device 700 includes four 1T1C memory cells which are electrically connected to one another. The cells include cell 1 (i.e., memory cell 700A) including transistor T13 and capacitor C13, cell 2 including transistor T14 and capacitor C14, cell 3 including transistor T15 and capacitor C15, cell 4 including transistor T16 and capacitor C16, cell 5 transistor T17 and capacitor C17, cell 6 including transistor T18 and capacitor C18, cell 7 including transistor T19 and capacitor C19, and cell 8 including transistor T20 and capacitor C20. Each of the transistors T13-T20 has a source electrode that is connected to the same bit line BL[0]. Each of the transistors T13 and T17 has a gate electrode that is connected to the word line WL[0], each of the transistors T14 and T18 has a gate electrode connected to the word line WL[3], each of the transistors T15 and T19 has a gate electrode connected to the word line WL[1], and each of the transistors T16 and T20 has a gate electrode connected to the word line WL[2]. Each of the capacitors C13-C16 has a first electrode (i.e., top electrode) connected to the source line SL[0], and each of the capacitors C17-C20 has a first electrode (i.e., top electrode) connected to the source line SL[1]. Each of the capacitors C13-C20 has a second electrode (i.e., bottom electrode) connected to the drain electrode of the transistors T13-T20, respectively. In some embodiments, the first electrodes of the capacitors C13-C20 include the top electrode 304 of capacitor 300A or the via 312 (which functions as a top electrode) of the capacitor 300B, and the second electrodes of the capacitors C13-C20 includes the bottom electrode 308 of the capacitor 300A or capacitor 300B.

Compared to the typical chip area for one-time programmable memory chips having a similar circuit being designed by the existing technologies, the memory cell 700 in some embodiments have approximately 43.8% reduction in chip area due to the MIM capacitor being formed in the metal layers over the source/drain electrode of the transistor.

FIG. 7B illustrates a layout of the capacitors C13-C20 for the memory device 700 illustrated in FIG. 7A, in accordance with some embodiments. Each of the capacitors C13-C20 is formed of a bottom electrode 702, an insulator 706, and a top electrode 704. Although the layout only shows several layers, this is for illustrative for purposes only and one of ordinary skill in the art will recognize that there can be additional layers above, below or in between the layers shown.

The layout for several layers of one of the memory cells of the memory device 700 can look like the layout in FIG. 7B. For example, for capacitor C13, the metal layer including the bottom electrode 702 can extend in the y-direction, and the metal layer including the top electrode can extend in the x-direction. At the intersection of the two metal layers and in between the two metal layers, an insulator 706 is formed such that the combination of the metal layers and the insulator 706 forms the capacitors C13-C20 of memory device 700. The bottom and top electrodes 702 and 704 are formed of metal. The bottom electrode 702 can be metal layer M5 in the interconnect structure, as discussed above, but is not limited thereto. The top electrode 704 can be metal layer M6 in the interconnect structure as discussed above, but is not limited thereto. For example, the bottom electrode 702 can be metal layer M6, and the top electrode can be metal layer M7.

FIGS. 7C-7F illustrate top-down views of various layers of the memory device 700 of FIG. 7A, in accordance with some embodiments. These layers are illustrated as an example of how the memory device 700 can be layered to form the transistors T13-T20 and an interconnect structure over the transistors to form the capacitors C13-C20. One of ordinary skill will recognize that memory device 700 can be laid out in layers in a different manner so as to form the electrical circuit shown in FIG. 7A. Each of the layouts in FIGS. 7C-7F illustrates 2 neighboring instances of the memory device 700 of FIG. 7A; in other words, there are 16 memory cells shown. Although not illustrated for clarity, there are a plurality of vias formed either through or in between the layers at different regions of the layers illustrated in FIGS. 7C-7F.

FIG. 7C illustrates the gate layer PO and active layer OD that form portions of 16 transistors, in accordance with some embodiments. The gate layer PO is formed of conductive material such as polysilicon and functions as the gates of the transistors. Other conductive materials for the gate layer PO, such as metals, are within the scope of various embodiments. The active layer OD is formed of semiconductor material and may include p-type dopants or n-type dopants. The active layer OD includes the source and drain terminals and the conduction channel of the transistors when the transistors are turned on. The gate layer PO extend in the y-direction, and the active layer OD extend in the x-direction.

FIG. 7D illustrates metal layers M0, M1, and M2, in accordance with some embodiments. The metal layer M0 is the lowermost metal layer of the interconnect structure that is formed over the transistors. The metal layer M1 is formed over the metal layer M0, and the metal layer M2 is formed over the metal layer M1. The metal layers M0 and M2 substantially overlap each other in FIG. 7D, but the layers are not limited thereto. The metal layers M0 and M2 extend in the x-direction, and M1 extends in the y-direction.

The metal layers M0 and M2 include the bit lines BL[0] and BL[1] carry the corresponding bit line signals. For example, when the bit line driver 116 drives a high voltage on BL[0], a portion of the metal layers M0 and M2 corresponding to the bit line BL[0] will have a high voltage. The metal layer M1 includes the word lines WL[0], WL[1], WL[2], WL[3], WL[4], WL[5], WL[6], and WL[7] that carry the corresponding word line signals. For example, when the word line driver 112 drives a high voltage to WL[0], the corresponding portion of the metal layer M1 will have a high voltage. The metal layers M0-M2 are also able to have any voltage driven (e.g., low voltage, no voltage) by the corresponding bit line driver 116 or word line driver 112.

FIG. 7E illustrates metal layers M3 and M4, in accordance with some embodiments. The metal layer M3 is formed over the metal layer M2, and the metal layer M4 is formed over the metal layer M3. At least portions of the metal layer M3 and metal layer M1 may be similarly patterned. Therefore, metal layer M1 and metal layer M3 may overlap in portions of the layout. Furthermore, metal layers M1 and M3 can be electrically coupled to each other in portions of the layout. Furthermore, portions of the metal layer M4 and metal layers M0 and M2 may be similarly patterned, and therefore metal layers M0, M2, and M4 may overlap in portions of the layout. Furthermore, the metal layers M0, M2, and M4 may be electrically coupled to each other in portions of the layout.

The metal layer M3 can include word lines WL[0]-WL[7] that carry the corresponding word line signals. For example, when the word line driver 112 tries to drive a high voltage on WL[0], a portion of the metal layer M3 that corresponds to the word line WL[0] will have a high voltage. The metal layer M4 can include bit lines BL[0]-BL[1] that carry the corresponding bit line signals. For example, when the bit line driver 116 tries to drive a high voltage on BL[0], portions of the metal layer M3 that correspond to the bit line BL[0] will have a high voltage. The metal layer M4 can also include dummy bit lines DMY. However, these dummy bit lines DMY are not electrically coupled to any of the bit line driver 116, word line driver 112, or source line driver 114 and are therefore not functional. The dummy bit lines DMY may be formed at the edge of the memory device 700.

FIG. 7F illustrates metal layers M5 and M6, in accordance with some embodiments. The metal layer M5 is formed over the metal layer M4, and the metal layer M6 is formed over the metal layer M5. As discussed above, there may be a capacitor formed where metal layer M5 and metal layer M6 overlap. When a dielectric insulator is formed between the metal layers M5 and M6, a MIM capacitor MIM is formed. The MIM capacitors shown in FIG. 7F can be the capacitors. In FIG. 7F, there are 16 MIM capacitors shown, but embodiments are not limited thereto and there can be more or fewer than 16 MIM capacitors.

The metal layer M6 can include source lines SL[0], SL[1], SL[2], and SL[3] that carry the corresponding source line signals. For example, when the source line driver 114 drives a high voltage on SL[0], a portion of the metal layer M6 that corresponds to the source line SL[0] will have a high voltage.

FIGS. 7G-7M illustrate various layers of a memory cell 700A of the memory device 700, in accordance with some embodiments. The memory cell 700A includes transistor T13 and capacitor C13 of FIG. 7A, but the present disclosure is not limited thereto, and the layouts can be applied to any of the 1T1C combinations of FIG. 7A. FIGS. 7G-7M serve to illustrate the various layers of an example memory cell 700A which include only one transistor T13 and one capacitor C13. The figures illustrate, among other things, the various metal layers, the vias that connect the various metal layers, and their relationships with the bit lines, word lines, and source lines. In However, the positions of the vias with respect to one another and the relative positions of the layers may not align vertically. Therefore, for clarity and simplicity purposes, the layers shown in the figures are not meant to overlap one another to show a top-down view of the layout, but one of ordinary skill in the art will recognize that the layers can be rearranged to form a layout of the memory cell.

Referring to FIG. 7G, the gate layer PO and the active layer OD of the memory cell 700A are shown, in accordance with some embodiments. Memory cell 700A includes transistor 708, which can include the transistor T13. A via 710A is formed over the gate layer PO to electrically connect the gate layer PO to a layer above (e.g., word line WL[0]). A via 712A is formed over the active layer OD to electrically connect the active layer OD to a layer above (e.g., bit line BL[0]). A via 714A is formed active layer OD that electrically connects the source terminal of the transistor T13 to a layer above (e.g., metal layer M5) that serves as the bottom electrode of capacitor C13.

Referring to FIG. 7H, metal layers M0 and M1 of the memory cell 700A are illustrated, in accordance with some embodiments. The metal layer M0 extends in the x-direction, and the metal layer M1 extends in y-direction. Vias 710B, 712B, and 714B are formed between the metal layers M0 and M1. Via 710B may overlap with via 710A, via 712B may overlap with via 712A, and via 714B may overlap with via 714A.

The metal layer M0 can function as the bit line BL[0]. In such embodiments, the bit line driver 116 can drive a bit line signal through the bit line BL[0] to the active layer OD through via 712A. Accordingly, the source electrode of the transistor T13 can be electrically connected to the bit line BL[0], as shown in FIG. 7A.

The metal layer M1 can function as the word line WL[0]. The word line driver 112 can drive a word line signal to the gate layer PO through the word line WL[0] to the gate layer PO through vias 710B and 710A. Accordingly, the gate of the transistor T13 can be electrically connected to the word line WL[0], as shown in FIG. 7A.

Referring to FIG. 7I, the metal layers M1 and M2 of the memory cell 700A are illustrated, in accordance with some embodiments. The metal layer M1 extends in the y-direction, and the metal layer M2 extends in the x-direction. Vias 710C, 712C, and 714C are formed between the metal layers M1 and M2. Via 710C may overlap with vias 710A-712B, via 712C may overlap with vias 712A-712B, and via 714C may overlap with vias 714A-712B. As discussed above, metal layer M1 can function as the word line WL[0].

The metal layer M2 can function as the bit line BL[0]. In such embodiments, the bit line driver 116 can drive a bit line signal through the bit line BL[0] to the active layer OD through vias 712A-712C. Accordingly, the source electrode of the transistor T13 can be electrically connected to the bit line BL[0], as shown in FIG. 7A.

Referring to FIG. 7J, the metal layers M2 and M3 of the memory cell 700A are illustrated, in accordance with some embodiments. The metal layer M2 extends in the x-direction, and the metal layer M3 extends in the y-direction. Vias 710D, 712D, and 714D are formed between the metal layers M2 and M3. Via 710D may overlap with vias 710A-710C, via 712D may overlap with vias 712A-712C, and via 714D may overlap with vias 714A-714C. As discussed above, metal layer M2 can function as the bit line [0].

The metal layer M3 can function as the word line WL[0]. In such embodiments, the word line driver 112 can drive a word line signal through the word line WL[0] to the gate layer PO through vias 710A-710D. Accordingly, the gate of the transistor T13 can be electrically connected to the word line WL[0], as shown in FIG. 7A.

Referring to FIG. 7K, the metal layers M3 and M4 of the memory cell 700A are illustrated, in accordance with some embodiments. The metal layer M3 extends in the y-direction, and the metal layer M4 extends in the x-direction. Vias 712E and 714E are formed between the metal layers M3 and M4. Via 712E may overlap with vias 712A-712D, and via 714E may overlap with vias 714A-714D. As discussed above, metal layer M3 can function as the word line [0].

The metal layer M4 can function as the bit line BL[0]. In such embodiments, the bit line driver 116 can drive a bit line signal through the bit line BL[0] to the active layer OD through vias 712A-712D. Accordingly, the source electrode of the transistor T13 can be electrically connected to the bit line BL[0], as shown in FIG. 7A.

As discussed with respect to FIG. 7E, a dummy bit line DMY can be formed. Referring to FIG. 7K, the metal layer M4 can include the dummy bit line DMY. However, the dummy bit line DMY does not function as an actual bit line and can be formed, for example, at the edge of a memory array.

Referring to FIG. 7L, the metal layers M4 and M5 of the memory cell 700A are illustrated, in accordance with some embodiments. The metal layer M4 extends in the x-direction, and the metal layer M5 extends in the y-direction. Via 714F is formed between the metal layers M4 and M5. Via 714F may overlap with vias 714A-714E. As discussed above, metal layer M4 can function as the bit line BL[0] or a dummy bit line DMY.

The metal layer M5 can function as the bottom electrode of the capacitor C13. Accordingly, the drain of the transistor T13 can be electrically connected to bottom electrode of the capacitor C13, as shown in FIG. 7A.

Referring to FIG. 7M, the metal layers M5 and M6 of the memory cell 700A are illustrated, in accordance with some embodiments. The metal layer M5 extends in the y-direction, and the metal layer M6 extends in the y-direction. As discussed above, the metal layer M5 can function as the bottom electrode of the capacitor.

The metal layer M6 can function as the top electrode of the capacitor C13. As discussed above, the memory cell 700A includes a MIM capacitor 716 that can include the capacitor C13. Although not shown, a dielectric insulator layer is formed between the metal layers M5 and M6 to form the MIM capacitor 716, and the bottom electrode formed on metal layer M5 is electrically connected to the drain of the transistor 708 through the vias 714A-714E. Accordingly, the MIM capacitor 716 is electrically connected to the transistor 708 of FIG. 7G. Furthermore, although not shown in FIG. 7M, a via can be formed between the metal layers M5 and M6.

The metal layer M6 can function as the source line SL[0]. In such embodiments, the source line driver 114 can drive a source line signal to the metal layer M6 through the source line SL[0] to the top electrode of the MIM capacitor. Accordingly, the top electrode of the capacitor C13 can be electrically connected to the source line SL[0], as shown in FIG. 7A.

Although FIGS. 7G-7M illustrate and describe metal layer M5 including the bottom electrode and the metal layer M6 including the top electrode of the capacitor 708 (and capacitor C13), the embodiments are not limited thereto. As described with reference to FIGS. 3A and 3B, the top electrode can be formed separately above the dielectric insulator and below the metal layer M6 (as illustrated in FIG. 3A), or when there is no separately formed top electrode, the via formed between the dielectric insulator and metal layer M6 may function as a top electrode (as illustrated in FIG. 3B).

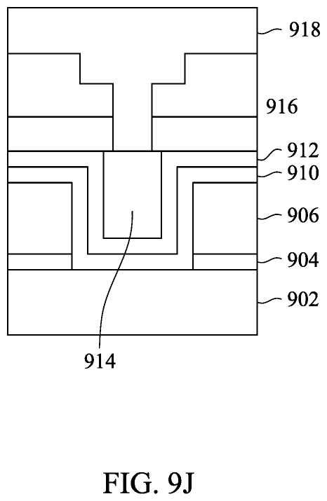

FIG. 8 illustrates a flow chart of an example method for making a MIM capacitor, in accordance with some embodiments. It should be noted that process 800 is merely an example, and is not intended to limit the present disclosure. Accordingly, it is understood that additional steps/operations may be provided before, during, and after process 800 of FIG. 8, and that some other operations may only be briefly described herein. Operations of process 800 may be associated with cross-sectional views of example MIM capacitor 300A at various fabrication stages as shown in FIGS. 9A-9J respectively, which will be discussed in further detail below.

In brief overview, the process 800 starts with operation 802 of forming a transistor on a substrate. Then, process 800 can proceed to operation 804 of forming a first metal layer. Then, process 800 can proceed to operation 806 of forming an oxide over the first metal layer. Then, process 800 can proceed to operation 808 of forming a porous low-k material over the oxide. Then, process 800 can proceed to operation 810 of etching a portion of the porous low-k material. Then, process 800 can proceed to operation 812 of etching a portion of the oxide. Then, process 800 can proceed to operation 814 of forming a first dielectric film. Then, process 800 can proceed to operation 816 of forming a second dielectric film. Then, process 800 can proceed to operation 818 of forming a top electrode. Then, process 800 can proceed to operation 820 of polishing the top electrode. Then, process 800 can proceed to operation 822 of forming an interlayer dielectric. Then, process 800 can proceed to operation 824 of defining a via in the interlayer dielectric. Then, process 800 can proceed to operation 826 of forming a metal layer over the exposed portion of the top electrode.

Operation 802 includes forming a transistor over a substrate (not shown). Although the transistor is not shown in the figures for simplicity, it is contemplated that the transistor can be any suitable type of transistor including, but not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like. After the transistor is formed, a back-end-of-line (BEOL) process is performed to connect an interconnect structure over the transistor.

Corresponding to operations 804, 806, and 808, FIG. 9A is a resulting cross-sectional view of the MIM capacitor 300A including a first metal layer 902, oxide 904, and a first inter-layer dielectric (ILD) 906, at one of the various stages of fabrication. The first metal layer 902 may be formed of at least one of W, TiN, TaN, Ru, Co, Al, Cu, or any conductive material. The oxide 904 may be formed of insulating material including, but not limited to, silicon dioxide, silicate glass, silicon oxycarbide, ZrO, TiO₂, HfOx, a high-k dielectric, or the like. The first ILD 906 may be formed of porous low-k dielectric material, such as silicon oxide, phosphosilicate glass (PSG), borosilicate glass (BSG), boron-doped phosphosilicate glass (BPSG), undoped silicate glass (USG), or the like, and may be deposited by any suitable method, such as CVD, PECVD, or FCVD.

The first metal layer 902 can function as the bottom electrode 308 of the MIM capacitor 300A. Accordingly, the first metal layer 902 can include metal layer M5 discussed above but is not limited thereto and can include any metal layer M5 formed above the semiconductor devices formed over the substrate.

Corresponding to operation 810, FIG. 9B is a cross-sectional view of the MIM capacitor 300A including a portion of the ILD 906 that has been etched, at one of the various stages of fabrication. The portion of the first ILD 906 to be etched has to be defined using a mask. The etching may be performed by any suitable method, for example, reactive ion etch (RIE), neutral beam etch (NBE), plasma etching, or the like, or combinations thereof.

Corresponding to operation 812, FIG. 9C is a cross-sectional view of the MIM capacitor 300A including a portion of the oxide 904 etched, at one of the various stages of fabrication. The etching may be performed by any suitable method, for example, reactive ion etch (RIE), neutral beam etch (NBE), plasma etching, or the like, or combinations thereof. After the operation 812, the resulting structure will include an etched portion 908.

Corresponding to operation 814, FIG. 9D is a cross-sectional view of the MIM capacitor 300A including first dielectric film 910, at one of the various stages of fabrication. The first dielectric film 910 may have a thickness of about 0.1 nanometers (nm) to around 50 nm but is not limited thereto. Changing the thickness of the first dielectric film 910 can result in a different breakdown voltage of the MIM capacitor 300A such that a circuit designer can design the a circuit including the MIM capacitor 300A to break down and program the memory cell including the MIM capacitor 300A at a desired voltage. When the MIM capacitor 300A is thick, the breakdown voltage will be greater, and when the MIM capacitor 300A is thin, the breakdown voltage will be smaller. The first dielectric film 910 can be formed of any suitable insulator material, for example, SiO₂, SiN, Al₂O₃, HfO, TaO, and the like. The first dielectric film 910 can be formed by any suitable method, for example, a molecular beam epitaxy (MBE) process, a chemical vapor deposition (CVD) process such as a metal organic CVD (MOCVD) process, low-pressure chemical vapor deposition (LPCVD), plasma enhanced chemical vapor deposition (PECVD), and/or other suitable epitaxial growth processes.

Corresponding to operation 816, FIG. 9E is a cross-sectional view of the MIM capacitor 300A including second dielectric film 912, at one of the various stages of fabrication. Although FIG. 9E illustrates the formation of the second dielectric film 912 having a similar thickness as first dielectric film 910, the thickness of the second dielectric film 912 is not limited thereto. The second dielectric film 912 may have a thickness of 0 nm to around 50 nm. In other words, the second dielectric film 912 may not be formed in order to reduce the thickness of the dielectric layer and/or the cost of fabrication.

The second dielectric film 912 can be formed of any suitable insulator material, for example, SiO₂, SiN, Al₂O₃, HfO, TaO, TaN, TiN, W, Ru, Co, Al, Cu, and the like. The first dielectric film 910 can be formed by any suitable method, for example, a molecular beam epitaxy (MBE) process, a chemical vapor deposition (CVD) process such as a metal organic CVD (MOCVD) process, low-pressure chemical vapor deposition (LPCVD), plasma enhanced chemical vapor deposition (PECVD), and/or other suitable epitaxial growth processes.

The first dielectric film 910, the second dielectric film 912, or a combination of both may function as the insulator 306 of the MIM capacitor 300A. A via 903 is formed as shown in FIG. 9E.

Corresponding to operation 818, FIG. 9F is a cross-sectional view of the MIM capacitor 300A including second metal layer 914, at one of the various stages of fabrication. The second metal layer 914 may be formed of at least one of W, TiN, TaN, Ru, Co, Al, Cu, or any conductive material.

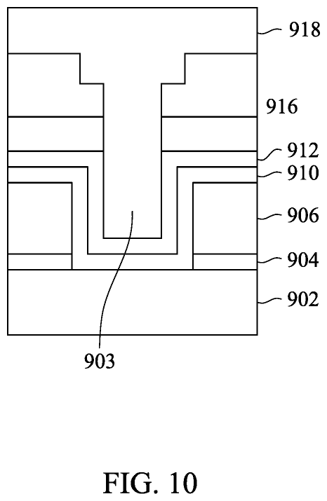

Corresponding to operation 820, FIG. 9G is a cross-sectional view of the MIM capacitor 300A including the second metal layer 914 that has been polished, at one of the various stages of fabrication. The thickness of the second metal layer 914 may be 0 nm to around 60 nm. The thickness may be 0 nm because the second metal layer 914 may be omitted (see FIG. 3B and FIG. 10).

The second metal layer 914 can function as the top electrode 304 of the MIM capacitor 300A as discussed above.

Corresponding to operation 822, FIG. 9H is a cross-sectional view of the MIM capacitor 300A including a second inter-layer dielectric (ILD) 916, at one of the various stages of fabrication. The second ILD 916 may be formed of porous low-k dielectric material, such as silicon oxide, phosphosilicate glass (PSG), borosilicate glass (BSG), boron-doped phosphosilicate glass (BPSG), undoped silicate glass (USG), or the like, and may be deposited by any suitable method, such as CVD, PECVD, or FCVD.

Corresponding to operation 824, FIG. 9I is a cross-sectional view of the MIM capacitor 300A including a portion of the second ILD 916 that has been etched, at one of the various stages of fabrication. The portion of the second ILD 916 to be etched has to be defined using a mask. The etching may be performed by any suitable method, for example, reactive ion etching (ME), neutral beam etching (NBE), plasma etching, or the like, or combinations thereof. The first dielectric film 910 and second dielectric film 912 may each have a step-like profile, in accordance with some embodiments.

For example, each of the first dielectric film 910 and second dielectric film 912 includes a vertical portion having two ends connected to two lateral portions that extend away from each other, respectively. As illustrated in FIG. 9I, the first dielectric film 910 includes a vertical portion 910A and two lateral portions 910B and 910C; and the second dielectric film 912 includes a vertical portion 912A and two lateral portions 912B and 912C. At least one of the lateral portion 910B or 910C, together with the vertical portion 910A, can form a step-like profile. Similarly, at least one of the lateral portion 912B or 912C, together with the vertical portion 912A, can form a step-like profile. In an example where the first dielectric film 910 functions as the sole insulator 306 of the MIM capacitor 300A, the lateral portion 910B can be in contact with the first metal layer 902, which functions as the bottom electrode 308 of the MIM capacitor 300A. In another example where the first dielectric film 910 and the second dielectric film 912 both function as the insulator 306 of the MIM capacitor 300A, through the lateral portion 910B, the lateral portion 912B can be coupled to the first metal layer 902, which functions as the bottom electrode 308 of the MIM capacitor 300A.

Corresponding to operation 826, FIG. 9J is a cross-sectional view of the MIM capacitor 300A including a third metal layer 918, at one of the various stages of fabrication. The third metal layer 918 may be formed of at least one of W, TiN, TaN, Ru, Co, Al, Cu, or any conductive material. The third metal layer 918 may include the metal layer M6 as discussed above but is not limited thereto. Accordingly, the third metal layer 918 may be electrically coupled to the second metal layer 914.

FIG. 10 is a cross-sectional view of the MIM capacitor 300B without a separately formed top electrode, at one of the various stages of fabrication. Referring to process 800, the operations 818-820 may be optionally skipped to form the MIM capacitor 300B. In other words, after the via 903 is formed operation 816, the process may proceed to step 822 to form the second ILD 916. Then the second ILD 916 is etched to the bottom of the via 903 to expose the first dielectric film 910 and/or the second dielectric film 912, depending on whether one or both films 910 and 912 are used. Then the third metal layer 918 may be formed over. Accordingly, the portion of the third metal layer formed in and over the via 903 (via 312 of FIG. 3B) may function as the top electrode for the MIM capacitor 300B. Accordingly, fabrication of the MIM capacitor 300B may reduce cost and time.

In one aspect of the present disclosure, a memory device is disclosed. The memory device includes a first transistor and a first capacitor electrically coupled to the first transistor, the first transistor and the first capacitor forming a first one-time-programmable (OTP) memory cell. The first capacitor has a first bottom metal terminal, a first top metal terminal, and a first insulation layer interposed between the first bottom and first top metal terminals. The first insulation layer comprises a first portion, a second portion separated from the first portion, and a third portion vertically extending between the first portion and the second portion. The first bottom metal terminal is directly below and in contact with the first portion of the first insulation layer.

In another aspect of the present disclosure, a memory device is disclosed. The memory device includes a substrate and a memory array, disposed over the substrate, and including a plurality of one-time-programmable (OTP) memory cells. The plurality of OTP memory cells are formed based on a plurality of first interconnect structures, a plurality of insulation layers, and a plurality of second interconnect structures, wherein each of the plurality of insulation layers comprises a step-like profile.

In yet another aspect of the present disclosure, a method of fabricating a memory device is disclosed. The method includes forming a transistor over a substrate and forming a first interconnect structure above the transistor to electrically couple to the transistor, wherein the first interconnect structure is disposed in a first metallization level. The method further includes exposing a portion of the first interconnect structure and forming a step-like insulation layer over the first interconnect structure, wherein a lateral portion of the step-like insulation layer contacts the exposed portion of the first interconnect structure. The method further includes forming a second interconnect structure over the lateral portion of the step-like insulation layer, thereby forming a capacitor based at least on the first interconnect structure, the lateral portion of the step-like insulation layer, and the second interconnect structure, wherein the transistor and capacitor collectively function as a one-time-programmable (OTP) memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a first transistor; and
a first capacitor electrically coupled to the first transistor, the first transistor and the first capacitor forming a first one-time-programmable (OTP) memory cell;
wherein the first capacitor has a first bottom metal terminal, a first top metal terminal, and a first insulation layer interposed between the first bottom metal terminal and first top metal terminal;
wherein the first insulation layer comprises a first portion, a second portion separated from the first portion, and a third portion vertically extending between the first portion and the second portion; and
wherein the first bottom metal terminal is directly below and in contact with the first portion of the first insulation layer.

2. The memory device of claim 1, wherein the first insulation layer has a dielectric material selected from the group consisting of: silicon oxide, silicon nitride, aluminum oxide, hafnium oxide, and tantalum oxide.

3. The memory device of claim 1, further comprising:
a first interconnect structure disposed in a first metallization layer and coupled to a source/drain terminal of the first transistor, wherein the first interconnect structure extends along a first lateral direction;
a second interconnect structure disposed in a second metallization layer and coupled to a gate terminal of the first transistor, wherein the second interconnect structure extends along a second lateral direction; and
a third interconnect structure disposed in a third metallization layer and coupled to the first top terminal of the first capacitor, wherein the third interconnect structure extends along one of the first or second lateral direction.

4. The memory device of claim 3, further comprising:
a second transistor; and
a second capacitor electrically coupled to the second transistor, the second transistor and the second capacitor forming a second OTP memory cell;
wherein the second capacitor has a second bottom metal terminal, a second top metal terminal, and a second insulation layer interposed between the second bottom and second top metal terminals;
wherein the second insulation layer comprises a first portion, a second portion separated from the first portion, and a third portion vertically extending between the first portion and the second portion; and
wherein the second bottom metal terminal is directly below and in contact with the first portion of the second insulation layer.

5. The memory device of claim 4, wherein each of the first and second bottom metal terminals extends along either the first or second lateral direction and is disposed in a fourth metallization layer above the second metallization layer and below the third metallization layer.

6. The memory device of claim 5, wherein each of the first and second top metal terminals includes a via structure coupling the fourth metallization layer to the third metallization layer.

7. The memory device of claim 5, wherein each of the first and second top electrodes includes a metal structure disposed below a via structure coupling the fourth metallization layer to the third metallization layer.

8. The memory device of claim 4, wherein the third interconnect structure is also coupled to the second top terminal of the second capacitor.

9. The memory device of claim 8, wherein the first and second insulation layers are physically separated from each other.

10. The memory device of claim 8, wherein the first and second insulation layers are formed as a one-piece structure.

11. A memory device, comprising:
a substrate;
a memory array, disposed over the substrate, that comprises a plurality of one-time-programmable (OTP) memory cells;
wherein the plurality of OTP memory cells are formed based on a plurality of first interconnect structures, a plurality of insulation layers, and a plurality of second interconnect structures, and wherein each of the plurality of insulation layers comprises a step-like profile.

12. The memory device of claim 11, wherein the step-like profile comprises at least one vertical portion and two lateral portions, and wherein the at least one vertical portion, with its two ends respectively connected to the lateral portions, is configured to be broken down by a voltage applied through a corresponding one of the second interconnect structures.

13. The memory device of claim 11, wherein
the plurality of first interconnect structures, extending along a first lateral direction, are disposed in a first metallization layer;
the plurality of second interconnect structures, extending along a second lateral direction perpendicular to the first lateral direction, are disposed in a second metallization layer higher than the first metallization layer; and
the plurality of insulation layers is disposed between the first and second metallization layers.

14. The memory device of claim 13, wherein each of the second interconnect structures is operatively shared by a subset of the memory cells arranged along the second lateral direction, each of the subset of memory cells includes a respective one of the insulation layers and a respective one of the first interconnect structures.

15. The memory device of claim 11, wherein
the plurality of first interconnect structures, extending along a first lateral direction, are disposed in a first metallization layer;
the plurality of second interconnect structures, also extending along the first lateral direction, are disposed in a second metallization layer higher than the first metallization layer; and
the plurality of insulation layers is disposed between the first and second metallization layers.

16. The memory device of claim 15, wherein each of the second interconnect structures is operatively shared by a subset of the memory cells arranged along the first lateral direction, each of the subset of memory cells includes a respective one of the insulation layers and a respective one of the first interconnect structures.

17. The memory device of claim 11, wherein
the plurality of first interconnect structures, extending along a first lateral direction, are disposed in a first metallization layer;
the plurality of second interconnect structures, extending along a second lateral direction perpendicular to the first lateral direction, are disposed in a second metallization layer higher than the first metallization layer; and
the plurality of insulation layers is disposed between the first and second metallization layers.

18. The memory device of claim 17, wherein each of the second interconnect structures is operatively shared by a subset of the memory cells arranged along the second lateral direction, each of the subset of memory cells includes a respective one of the first interconnect structures, and the subset of memory cells share one of the insulation layers.

19. A method for fabricating a memory device, comprising:
forming a transistor over a substrate;
forming a first interconnect structure above the transistor to electrically couple to the transistor, wherein the first interconnect structure is disposed in a first metallization level;
exposing a portion of the first interconnect structure;
forming a step-like insulation layer over the first interconnect structure, wherein a lateral portion of the step-like insulation layer contacts the exposed portion of the first interconnect structure; and
forming a second interconnect structure over the lateral portion of the step-like insulation layer, thereby forming a capacitor based at least on the first interconnect structure, the lateral portion of the step-like insulation layer, and the second interconnect structure;
wherein the transistor and capacitor collectively function as a one-time-programmable (OTP) memory cell.

20. The method of claim 19, wherein the second interconnect structure includes a via structure coupling a second metallization layer to the first metallization layer, or a metal structure disposed below the via structure, and wherein the second metallization layer is disposed next upper to the first metallization layer.
